(19) United States
(12) Patent Application Publication
(10) Pub. No.: US 2026/0024557 A1
(43) Pub. Date: Jan. 22, 2026

(54) SEMICONDUCTOR DEVICES WITH STACKED STRUCTURES

(71) Applicant: Yangtze Memory Technologies Co., Ltd., Wuhan (CN)

(72) Inventors: Tian CHEN, Wuhan (CN); Lei HUANG, Wuhan (CN); Kun ZHANG, Wuhan (CN); Yuhui HAN, Wuhan (CN); Zhong ZHANG, Wuhan (CN); Wenxi ZHOU, Wuhan (CN); Zhiliang XIA, Wuhan (CN)

(21) Appl. No.: 18/797,437

(22) Filed: Aug. 7, 2024

(30) Foreign Application Priority Data
Jul. 22, 2024 (CN) 202410985300.3

(51) Int. Cl. G11C 5/06; G11C 16/04; H01L 23/528; H10B 41/10; H10B 41/27; H10B 41/35; H10B 41/40; H10B 43/10; H10B 43/27; H10B 43/35; H10B 43/40

(52) U.S. Cl. CPC G11C 5/063; G11C 16/0483; H01L 23/5283; H10B 41/10; H10B 41/27; H10B 41/35; H10B 41/40; H10B 43/10; H10B 43/27; H10B 43/35; H10B 43/40

(57) ABSTRACT

The present disclosure relates to methods, devices, systems, and techniques for managing semiconductor devices with stacked structures. An example semiconductor device includes a control semiconductor structure and array semiconductor structures. The array semiconductor structures are stacked along a first direction and are coupled to the control semiconductor structure. The array semiconductor structures include at least a first array semiconductor structure and a second array semiconductor structure. The first array semiconductor structure includes: a first array region; a first connection region adjacent to the first array region along a second direction perpendicular to the first direction; first bit line connection structures in the first array region; first word line contact structures extending along the first direction in the first connection region; and first word line connection structures extending along the first direction in the first connection region.

### CROSS-REFERENCE TO RELATED APPLICATIONS

This application claims priority to Chinese Patent Application No. 202410985300.3, filed on Jul. 22, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing semiconductor devices with stacked structures.

One aspect of the present disclosure features a semiconductor device. The semiconductor device includes a control semiconductor structure; and array semiconductor structures stacked along a first direction and coupled to the control semiconductor structure. The array semiconductor structures include at least a first array semiconductor structure and a second array semiconductor structure. The first array semiconductor structure includes: a first array region and a first connection region adjacent to the first array region along a second direction perpendicular to the first direction; a first stack of conductive layers and isolating layers alternating with each other along the first direction; a first interconnect layer; first bit lines in the first array region; and first bit line connection structures in the first array region. The first bit line connection structures are coupled to the first bit lines and extend through the first stack along the first direction. The first array semiconductor structure further includes first word line contact structures extending along the first direction in the first connection region and first word line connection structures extending through the first stack along the first direction in the first connection region. The second array semiconductor structure includes: a second interconnect layer; second bit lines coupled to the first bit line connection structures through the second interconnect layer; and second word line contact structures extending along the first direction and being coupled to the first word line connection structures through the second interconnect layer.

In some implementations, one of the first bit line connection structures is coupled to a corresponding first bit line of the first bit lines and a corresponding second bit line of the second bit lines, the corresponding first bit line of the first bit lines and the corresponding second bit line of the second bit lines are aligned along the first direction, and one of the first word line connection structures is coupled to a corresponding second word line contact structure of the second word line contact structures.

In some implementations, the control semiconductor structure is bonded to the first array semiconductor structure through a first bonding structure, and the first array semiconductor structure is bonded to the second array semiconductor structure through a second bonding structure.

In some implementations, the first array semiconductor structure further includes a first conductive structure outside the first array region and the first connection region, the first conductive structure is coupled to the control semiconductor structure through the first interconnect layer, the second array semiconductor structure further includes a second conductive structure, the second conductive structure is coupled to the first conductive structure through the second interconnect layer, and the second conductive structure is aligned with the first conductive structure along the first direction.

In some implementations, the first array semiconductor structure further includes a third interconnect layer, the first stack is between the first interconnect layer and the third interconnect layer along the first direction, and the first bit line connection structures, the first word line connection structures, and the first conductive structure are coupled between the first interconnect layer and the third interconnect layer.

In some implementations, the first array semiconductor structure includes a first peripheral region adjacent to the first array region and the first connection region along a third direction perpendicular to the first direction and the second direction. The first conductive structure is in the first peripheral region. The first array region includes a center region and an edge region arranged along the third direction. The edge region is in one side of the first array region along the third direction. The first bit line connection structures are in the edge region. The center region is between the edge region and the first peripheral region along the third direction.

In some implementations, the first array semiconductor structure includes a first peripheral region adjacent to the first array region and the first connection region along a third direction perpendicular to the first direction and the second direction. The first conductive structure is in the first peripheral region. The first array region includes a center region, a first edge region, and a second edge region arranged along the third direction. The first edge region and the second edge region are in two opposite sides of the first array region along the third direction. A first set of the first bit line connection structures are in the first edge region. A second set of the first bit line connection structures are in the second edge region. The center region is between the first edge region and the second edge region along the third direction. The second edge region is between the center region and the first peripheral region along the third direction.

In some implementations, the first word line connection structures and the first word line contact structures are arranged along a line extending in the second direction, the first word line connection structures are next to each other, and the first word line contact structures are next to each other.

In some implementations, the first word line connection structures and the first word line contact structures are arranged along a line extending in the second direction, and each of the first word line connection structures is next to a corresponding first word line contact structure of the first word line contact structures.

In some implementations, the first word line connection structures are arranged along a first line extending in the second direction, the first word line contact structures are arranged along a second line extending in the second direction, and the first word line connection structures are adjacent to the first word line contact structures along a third direction perpendicular to the first direction and the second direction.

In some implementations, the control semiconductor structure includes page buffer circuits, first string drivers coupled to the first word lines contact structures, and second string drivers coupled to the second word lines contact structures through the first word line connection structures. One of the page buffer circuits is coupled to a corresponding first bit line of the first bit lines and a corresponding second bit line of the second bit lines. The corresponding first bit line of the first bit lines is coupled to the corresponding second bit line of the second bit lines through a first bit line connection structure of the first bit line connection structures.

Another aspect of the present disclosure features a semiconductor device including a control semiconductor structure; and array semiconductor structures stacked along a first direction and coupled to the control semiconductor structure. The array semiconductor structures include at least a first array semiconductor structure, a second array semiconductor structure, and a third array semiconductor structure. The first array semiconductor structure includes: a first array region and a first connection region adjacent to the first array region along a second direction perpendicular to the first direction; a first stack of conductive layers and isolating layers alternating with each other along the first direction; a first interconnect layer; first bit lines in the first array region; and first bit line connection structures in the first array region. The first bit line connection structures are coupled to the first bit lines and extend through the first stack along the first direction. The first array semiconductor structure further includes first word line contact structures extending along the first direction in the first connection region and first word line connection structures extending through the first stack along the first direction in the first connection region. The second array semiconductor structure includes: a second array region and a second connection region adjacent to the second array region along the second direction; a second stack of conductive layers and isolating layers alternating with each other along the first direction; a second interconnect layer; and second bit lines in the second array region. The second bit lines are coupled to the first bit line connection structures. The second array semiconductor structure further includes: second bit line connection structures in the second array region; second word line contact structures extending along the first direction in the second connection region and being coupled to a first set of the first word line connection structures through the second interconnect layer; and second word line connection structures extending through the second stack along the first direction in the second connection region and being coupled to a second set of the first word line connection structures through the second interconnect layer. The second bit line connection structures are coupled to the second bit lines and extend through the second stack along the first direction. The third array semiconductor structure include: a third interconnect layer; third bit lines coupled to the second bit line connection structures; and third word line contact structures extending along the first direction and being coupled to the second word line connection structures through the third interconnect layer. A quantity of the first word line connection structure is equal to or greater than a sum of a quantity of the second word line contact structures and a quantity of the third word line contact structures.

In some implementations, the first array semiconductor structure further includes a first conductive structure outside the first array region and the first connection region, the first conductive structure is coupled to the control semiconductor structure though the first interconnect layer, the second array semiconductor structure further includes a second conductive structure outside the second array region and the second connection region, the second conductive structure is coupled to the first conductive structure through the second interconnect layer, the third array semiconductor structure further includes a third conductive structure coupled to the second conductive structure through the third interconnect layer, and the first conductive structure, the second conductive structure, and the third conductive structure are aligned along the first direction.

In some implementations, the first array semiconductor structure includes a first peripheral region adjacent to the first array region and the first connection region along a third direction perpendicular to the first direction and the second direction. The first conductive structure is in the first peripheral region. The first array region includes a center region and an edge region arranged along the third direction. The edge region is in one side of the first array region along the third direction. The first bit line connection structures are in the edge region. The center region is between the edge region and the first peripheral region along the third direction.

In some implementations, the control semiconductor structure includes page buffer circuits, where one of the page buffer circuits is coupled to a corresponding first bit line of the first bit lines, a corresponding second bit line of the second bit lines, and a corresponding third bit line of the third bit lines. The corresponding first bit line of the first bit lines is coupled to the corresponding second bit line of the second bit lines through a first bit line connection structure of the first bit line connection structures. The corresponding second bit line of the second bit lines is coupled to the corresponding third bit line of the third bit lines through a second bit line connection structure of the second bit line connection structures. The control semiconductor structure further includes first string drivers coupled to the first word lines contact structures; second string drivers coupled to the second word lines contact structures through the first set of the first word line connection structures; and third string drivers coupled to the third word lines contact structures through the second set of the first word line connection structures and the second word line connection structures.

In some implementations, the first set of the first word line connection structures are arranged along a first line extending in the second direction, the second set of the first word line connection structures are arranged along a second line extending in the second direction, the first word line contact structures are arranged along a third line extending in the second direction, and the first word line contact structures are between the first set of the first word line connection structures and the second set of the first word line connection structures along a third direction perpendicular to the first direction and the second direction.

A further aspect of the present disclosure features a method for forming a semiconductor device. The method includes forming a first array semiconductor structure of the semiconductor device. The first array semiconductor structure includes: a first array region and a first connection region adjacent to the first array region along a second direction perpendicular to a first direction; a first stack of conductive layers and isolating layers alternating with each other along the first direction; a first interconnect layer; and first bit lines in the first array region. The method further includes forming a second array semiconductor structure of the semiconductor device. The second array semiconductor structure includes a second interconnect layer and second bit lines. The method further includes forming a control semiconductor structure of the semiconductor device. The control semiconductor structure includes peripheral circuits configured to control the first array semiconductor structure and the second array semiconductor structure. The method further includes stacking the control semiconductor structure, the first array semiconductor structure, and the second array semiconductor structure along the first direction.

In some implementations, the method further includes: bonding the control semiconductor structure to the first array semiconductor structure using a first bonding structure; and bonding the first array semiconductor structure to the second array semiconductor structure using a second bonding structure.

In some implementations, forming the first array semiconductor structure includes forming first bit line connection structures in the first array region. The first bit line connection structures are coupled to the first bit lines and extend through the first stack along the first direction, and the first bit line connection structures are coupled to the second bit lines. Forming the first array semiconductor structure further includes forming first word line contact structures extending along the first direction in the first connection region, and forming first word line connection structures extending through the first stack along the first direction in the first connection region. Forming the second array semiconductor structure include forming second word line contact structures extending along the first direction, The second word line contact structures are configured to be coupled to the first word line connection structures through the second interconnect layer.

In some implementations, the first word line connection structures and the first word line contact structures are arranged along a line extending in the second direction, the first word line connection structures are next to each other, and the first word line contact structures are next to each other.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates a schematic view of a cross-section of an example three-dimensional (3D) memory device.

FIG. 2 illustrates a schematic circuit diagram of an example memory device.

FIG. 3 illustrates example peripheral circuits of the memory device in FIG. 2.

FIG. 4 illustrates schematic circuit diagrams of example word line driver and page buffer in FIG. 3.

FIGS. 5A-5D illustrate an example semiconductor device.

FIGS. 6A-6D illustrate another example semiconductor device.

FIGS. 7A(1)-7E(2) illustrate example arrangements of word line contact structures and word line connection structures in a semiconductor device.

FIG. 8 illustrates a flow chart of an example process for forming a semiconductor device.

FIG. 9 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

One crucial aspect of memory devices is their storage density, which refers to the amount of data that can be stored within a given physical area. Higher storage density is desirable because it allows for more information to be stored in a compact space. As technology advances, there is a constant push to increase storage density to meet the growing demands for data storage in various applications, such as consumer electronics, data centers, and mobile devices. Increasing memory storage density can be challenging due to physical limitations, electrical interference, manufacturing difficulties, etc.

Implementations of the present disclosure provide systems, devices, methods, and techniques for managing semiconductor devices with stacked structures, which can address one or more of the aforementioned issues. In some implementations, a semiconductor device includes a control semiconductor structure and array semiconductor structures stacked along a vertical direction and coupled to the control semiconductor structure. Each array semiconductor structure can include a stack of alternating conductive layers and isolating layers, bit lines, and one or more of bit line connection structures, word line contact structures, and word line connection structures. The bit lines of one array semiconductor structure can be coupled to corresponding peripheral circuits in the control semiconductor structure through bit line connection structures of other array semiconductor structures. The word line contact structures of one array semiconductor structure can be coupled to corresponding peripheral circuits in the control semiconductor structure through word line connection structures of other array semiconductor structures.

Implementations of the present disclosure can provide one or more of the following technical advantages and/or benefits. Control circuits (e.g., the peripheral circuits) of the semiconductor device can be separated from the array semiconductor structures and integrated into the control semiconductor structure that is stacked on the array semiconductor structures, thereby reducing the chip area.

In contrast to the semiconductor structures which include both memory arrays and peripheral circuits, the control semiconductor structure can be configured to only include peripheral circuits without memory arrays, which may require less interconnection vias and/or conductive lines than the semiconductor structures. This enables larger pitches for via or interconnection contacts in the semiconductor structures, e.g., through-silicon-vias (TSV), through-silicon-contact (TSC), or other types of vias. This larger pitch contributes to a broader process window, which, in turn, simplifies the manufacturing process and reduces costs.

In addition, the described techniques can increase storage capacity and density using lower cost fabrication processes compared to adding more decks to the stack of conductive layers and isolating layers and increasing the number of layers of each deck.

Moreover, the control semiconductor structure and the array semiconductor structure can be manufactured separately on separate semiconductor substrates such that a limitation (e.g., thermal budget) of fabricating one of them does not limit the processes of fabricating another. High thermal budgets are often required for advanced manufacturing techniques, such as annealing processes in memory technologies. Because of enhanced thermal budget management, the techniques implemented herein give better control over the manufacturing processes, leading to improved yield and reduced variability in the performance of semiconductor devices.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

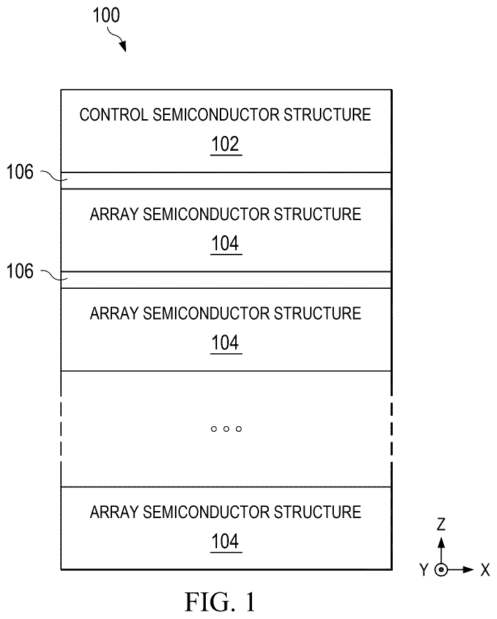

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a schematic view of a cross-section of an example 3D memory device 100. In the example of FIG. 1, the 3D memory device 100 can be a bonded chip. The 3D memory device 100 can include a control semiconductor structure 102 and one or more array semiconductor structures 104 stacked along a vertical direction (e.g., the Z direction). Each of the array semiconductor structures 104 can include an array of memory cells (also referred to as a memory cell array or a memory array). In some implementations, the memory array includes an array of NAND Flash memory cells provided in the form of 3D NAND memory strings. While for ease of description, a NAND Flash memory array may be used as an example in the present disclosure, it is understood that the memory array in the array semiconductor structures 104 may include any suitable types of memory cells, including but not limited to, NAND Flash memory cells, dynamic random access memory (DRAM) cells, static random access memory (SRAM) cells, NOR Flash memory cells, phase change memory (PCM) cells, resistive memory cells, magnetic memory cells, spin transfer torque (STT) memory cells, or any combination thereof.

The memory cells in the array semiconductor structure 104 can be organized into pages or fingers, which are then organized into blocks in which each memory cell is electrically connected to a separate line called a bit line (BL). All cells with the same vertical position in the NAND memory block can be electrically connected through the control gates by a word line (WL). In some implementations, a plane contains a certain number of blocks that are electrically connected through the same bit line. The array semiconductor structure 104 can include one or more planes.

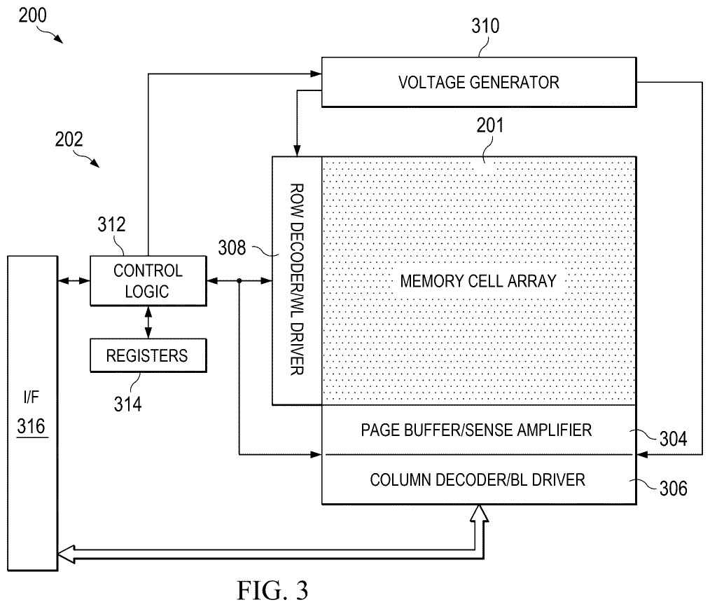

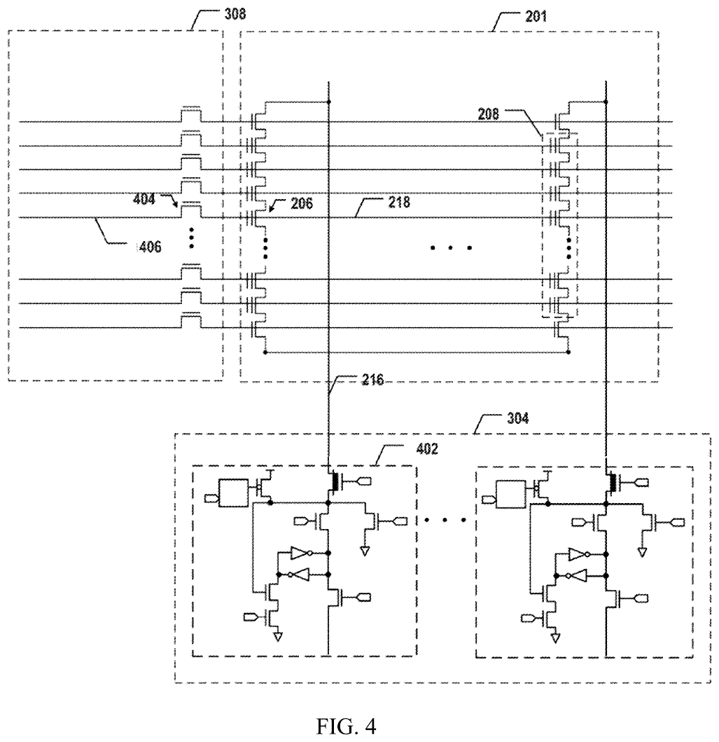

The control semiconductor structure 102 includes peripheral circuits configured to perform read/program and write/erase operations of the memory array of each array semiconductor structure 104. The peripheral circuits can include any suitable digital, analog, and/or mixed-signal circuits used for facilitating the operations of the memory array. For example, the peripheral circuits can include one or more of a page buffer (e.g., the page buffer 304 of FIGS. 3-4), a decoder (e.g., a row decoder and a column decoder), a sense amplifier, a driver (e.g., a word line driver 308 of FIGS. 3-4), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). In some implementations, the peripheral circuits in the control semiconductor structure 102 can use complementary metal-oxide semiconductor (CMOS) technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 104 are above 22 nm to reduce leakage current, maintain certain voltage levels (e.g., 1.2 V and above), and to reduce the cost.

As shown in FIG. 1, the 3D memory device 100 further includes bonding structures 106. Each of the bonding structures 106 can be disposed vertically (e.g., along Z direction) between the control semiconductor structure 102 and the array semiconductor structure 104 adjacent to the control semiconductor structure 102 or between two adjacent array semiconductor structures 104. In some implementations, the control semiconductor structure 102 and the array semiconductor structure 104 (or two adjacent array semiconductor structures 104) are jointed vertically through bonding techniques such as hybrid bonding. Hybrid bonding, also known as “metal/dielectric hybrid bonding,” is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. In some implementations, the bonding structure 106 can include a first bonding layer in contact with one semiconductor structure (e.g., the control semiconductor structure 102) and a second bonding layer in contact with another semiconductor structure (e.g., the array semiconductor structure 104 adjacent to the control semiconductor structure 102). In some instances, the first bonding layer of the bonding structure 106 can be considered as a part of the semiconductor structure on the top (e.g., the control semiconductor structure 102), and the second bonding layer of the bonding structure 106 can be considered as a part of the semiconductor structure on the bottom (e.g., the array semiconductor structure 104). The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be same or different, e.g., according to actual fabrication needs. Each of the second conductive structures can correspond to a first conductive structure of the first conductive structures. As such, when the control semiconductor structure 102 and the array semiconductor structure 104 are stacked together, the second conductive structures can be in contact with the corresponding first conductive structures to form conductive bonding (e.g., metal-to-metal bonding) through the bonding structure 106. Data transfer between the memory array in the array semiconductor structure 104 and the peripheral circuits in the control semiconductor structure 102 can be performed through the first and second conductive structures in the bonding structure 106.

In some implementations, the control semiconductor structure 102 and the array semiconductor structures 104 can be fabricated separately (e.g., in parallel) such that the thermal budget of fabricating one of them does not limit the processes of fabricating another. Moreover, a large number of interconnects can be formed through bonding structures 106 to make direct, short-distance (e.g., micron-level) electrical connections between the control semiconductor structure 102 and the array semiconductor structures 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. By vertically (e.g., along Z direction) integrating the control semiconductor structure 102 and the array semiconductor structures 104, the chip size can be reduced, and the memory cell density can be increased.

While for case of description, semiconductor devices including one control semiconductor structure and two or three array semiconductor structures may be used as examples in the present disclosure, it is understood that the described techniques can be applied to a semiconductor device having any suitable number (e.g., two or more) of control semiconductor structures and any suitable number (e.g., one, four, or even more) of array semiconductor structures.

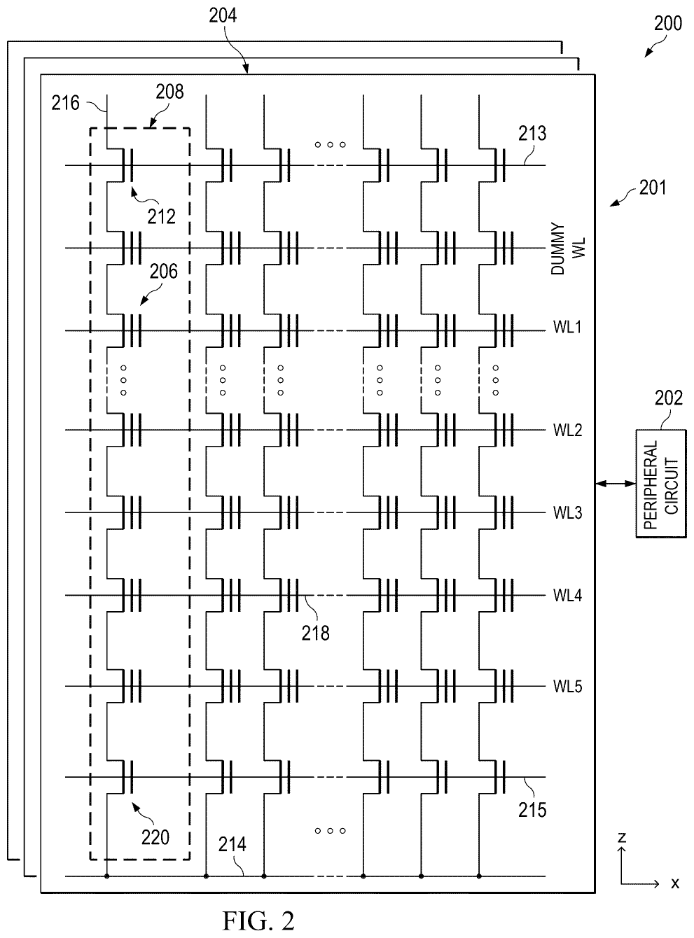

FIG. 2 illustrates a schematic circuit diagram of an example memory device 200 (e.g., the 3D memory device 100 of FIG. 1) including peripheral circuits. The memory device 200 can include a memory array 201 and peripheral circuits 202 coupled to the memory array 201. The memory array 201 can be in a semiconductor structure (e.g., one of the array semiconductor structures 104 of FIG. 1), and the peripheral circuits 202 can be in another semiconductor structure (e.g., the control semiconductor structure 102 of FIG. 1). The memory array 201 can be a NAND Flash memory array in which memory cells 206 are provided in the form of an array of NAND memory strings 208 each extending vertically above a substrate (not shown). In some implementations, each NAND memory string 208 includes a plurality of memory cells 206 coupled in series and stacked vertically (e.g., along Z direction). Each memory cell 206 can hold a continuous, analog value, such as an electrical voltage or charge that depends on the number of electrons trapped within a storage layer of the memory cell 206. The logic state (e.g., data) of each memory cell 206 in the block 204 can be determined based on the threshold voltage of the memory cell 206. Each memory cell 206 can be a floating gate type memory cell including a floating-gate transistor, or a charge trap type memory cell including a charge-trap transistor.

In some implementations, each memory cell 206 is a single-level cell (SLC) with two possible memory states that can store one bit of data. For example, the first memory state “0” can correspond to a first range of voltages, and the second memory state “1” can correspond to a second range of voltages. In some implementations, each memory cell 206 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 2, each NAND memory string 208 can include a source select gate (SSG) 210 at its source end and a drain select gate (DSG) 212 at its drain end. The SSG 210 and the DSG 212 can be configured to activate selected NAND memory strings 208 (columns of the array) during read and program operations. In some implementations, the sources of NAND memory strings 208 in the same block 204 are coupled through a same source line (SL) 214, e.g., a common SL. In other words, NAND memory strings 208 in the same block 204 have an array common source (ACS), according to some implementations. The DSG 212 of each NAND memory string 208 is coupled to a respective bit line 216 from which data can be read or written via an output bus (not shown), according to some implementations. In some implementations, the bit line 216 can extend along a horizontal direction (e.g., Y direction) to couple more than one memory string 208. In some implementations, each NAND memory string 208 is configured to be selected or deselected by applying a select voltage (e.g., above the threshold voltage of the transistor having the DSG 212) or a deselect voltage (e.g., 0 V) to the respective DSG 212 through one or more DSG lines 213, and/or by applying a select voltage (e.g., above the threshold voltage of the transistor having the SSG 210) or a deselect voltage (e.g., 0 V) to the respective SSG 210 through one or more SSG lines 215.

As shown in FIG. 2, NAND memory strings 208 can be organized into multiple blocks 204, each of which can have a common source line 214 coupled to the ACS. In some implementations, each block 204 can serve as a basic data unit for erase operations, such that memory cells 206 on the same block 204 are erased at the same time. To erase memory cells 206 in a selected block 204, the source lines 214 coupled to the selected block 204 and unselected blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of blocks or fractions of a block.

The memory cells 206 of adjacent NAND memory strings 208 can be coupled through word lines 218. In some implementations, the word line 218 can extend along a horizontal direction (e.g., X direction). The word line 218 can select which row of memory cells 206 is affected by read and program operations. In some implementations, the memory cell 206 is a SLC, and each word line 218 is coupled to a page of memory cells 206, which is the basic data unit for program operations. If the memory cell 206 is an MLC that stores two bits of data per cell, each word line 218 can correspond to two pages. If memory cell 206 is a TLC, each word line 218 can correspond to three pages. If memory cell 206 is a QLC, each word line 218 can correspond to four pages. The size of a page in bits is associated with the number of NAND memory strings 208 coupled by word line 218 in a block 204. Each word line 218 can include a gate line coupled to a plurality of control gates (gate electrodes) of a plurality of memory cells 206 in the respective page. Example word lines shown in FIG. 1 include dummy WL, WL1, WL2, WL3, WL4, and WL5 that are between one or more DSG lines 213 and one or more SSG lines 215.

FIG. 3 illustrates example peripheral circuits 202 of the memory device 200 in FIG. 2. The peripheral circuits 202 can be coupled to the memory array 201 through bit lines 216, word lines 218, source lines 214, SSG lines 215, and DSG lines 213. The peripheral circuits 202 can include any suitable analog, digital, and mixed-signal circuits for facilitating the operations of the memory array 201 by applying and sensing voltage signals and/or current signals to and from each target memory cell 206 through bit lines 216, word lines 218, source lines 214, SSG lines 215, and DSG lines 213. In some implementations, the peripheral circuits 202 can include various types of peripheral circuits formed using metal-oxide-semiconductor (MOS) technologies. The example peripheral circuits include a page buffer 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well. In some examples, the peripheral circuits 202 include at least one of the page buffer 304, the column decoder/bit line driver 306, the row decoder/word line driver 308, the voltage generator 310, the control logic 312, the registers 314, or the interface 316.

The page buffer 304 can be configured to read and program (write) data from and to memory array 201 according to the control signals from control logic 312. In an example, the page buffer 304 may store one page of program data (write data) to be programmed into one page of the memory array 201. In another example, the page buffer 304 may perform program verify operations to ensure that the data has been properly programmed into memory cells 206 coupled to selected word lines 218. In still another example, the page buffer 304 may also sense the low power signals from the bit line 216 that represents a data bit stored in memory cell 206, and amplify the small voltage swing to recognizable logic levels in a read operation. The column decoder/bit line driver 306 can be configured to be controlled by the control logic 312 and select one or more NAND memory strings 208 by applying bit line voltages generated from the voltage generator 310.

The row decoder/word line driver 308 can be configured to be controlled by the control logic 312 and select/deselect blocks 204 of the memory array 201 and select/deselect word lines 218 of the block 204. The row decoder/word line driver 308 can be further configured to drive word lines 218 using word line voltages generated from the voltage generator 310. In some implementations, the row decoder/word line driver 308 can also select/deselect and drive SSG lines 215 and DSG lines 213. As described below in detail, the row decoder/word line driver 308 is configured to apply a program voltage to selected word line 218 in a program operation on memory cell 206 coupled to selected word line 218.

The voltage generator 310 can be configured to be controlled by the control logic 312 and generate the word line voltages (e.g., read voltage, program voltage, pass voltage, local voltage, verify voltage, etc.), bit line voltages, and source line voltages to be supplied to the memory array 201.

The control logic 312 can be coupled to each peripheral circuit described above and configured to control operations of each peripheral circuit. The registers 314 can be coupled to the control logic 312 and include status registers, command registers, and address registers for storing status information, command operation codes, and command addresses for controlling the operations of each peripheral circuit.

The interface 316 can be coupled to the control logic 312 and act as a control buffer to buffer and relay control commands received from a host (not shown) to the control logic 312 and status information received from the control logic 312 to the host. The interface 316 can also be coupled to the column decoder/bit line driver 306 via a data bus, and act as a data input/output (I/O) interface and a data buffer to buffer and relay data to and from the memory array 201.

FIG. 4 illustrates schematic circuit diagrams of example word line driver 308 and page buffer 304 of FIG. 3. In some implementations, page buffer 304 can include a plurality of page buffer circuits 402 each coupled to one 3D NAND memory string 208 via a respective bit line 216. That is, memory device 200 can include bit lines 216 respectively coupled to 3D NAND memory strings 208, and page buffer 304 can include page buffer circuits 402 respectively coupled to bit lines 216 and 3D NAND memory strings 208. Each page buffer circuit 402 can include one or more latches, switches, supplies, nodes (e.g., data nodes and I/O nodes), current mirrors, verify logic, sense circuits, etc. In some implementations, each page buffer circuit 402 is configured to store sensing data received from a respective bit line 216, e.g., sensing current, corresponding to read data. Each page buffer circuit 402 can also be configured to output the stored sensing data to at the time of the read operation. Each page buffer circuit 402 can be further configured to store program data and output the stored program data to a respective bit line 216 at the time of the program operation.

In some implementations, word line driver includes a plurality of string drivers 404 (a.k.a. driving elements) respectively coupled to word lines 218. Word line driver 308 can also include a plurality of local word lines 406 (LWLs) respectively coupled to string drivers 404. Each string driver 404 can include a gate coupled to a row decoder 408, a source/drain coupled to a respective local word line 406, and another source/drain coupled to a respective word line 218. In some implementations, gates of two or more string drivers 404 are coupled to the same row decoder 408. For example, each memory block can have its corresponding row decoder 408. String drivers 404 coupled to word lines 218 in one memory block can be coupled to the same row decoder 408. In some memory operations, the row decoder 408 can select or unselect its corresponding memory block. For example, the row decoder 408 can apply a select voltage (e.g., a voltage higher than the threshold voltage of string drivers 404) on the gates of the string drivers 404 of the corresponding memory block, so that the corresponding memory block is selected. In contrast, the row decoder 408 can apply an unselect voltage (e.g., a voltage lower than the threshold voltage of string drivers 404) on the gates of the string drivers 404 of the corresponding memory block, so that the corresponding memory block is unselected. In some implementations, the peripheral circuits can include other circuits configured to select one or more particular string drivers 404 of the selected memory block, and apply a voltage (e.g., program voltage, pass voltage, or erase voltage) to each local word line 406, such that the voltage is applied by each selected string driver 404 to a respective word line 218.

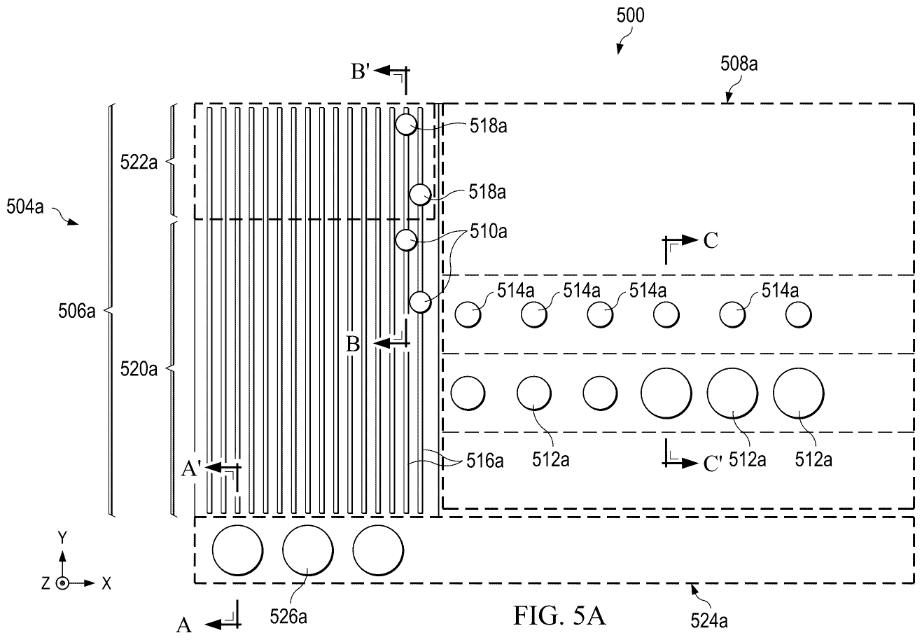

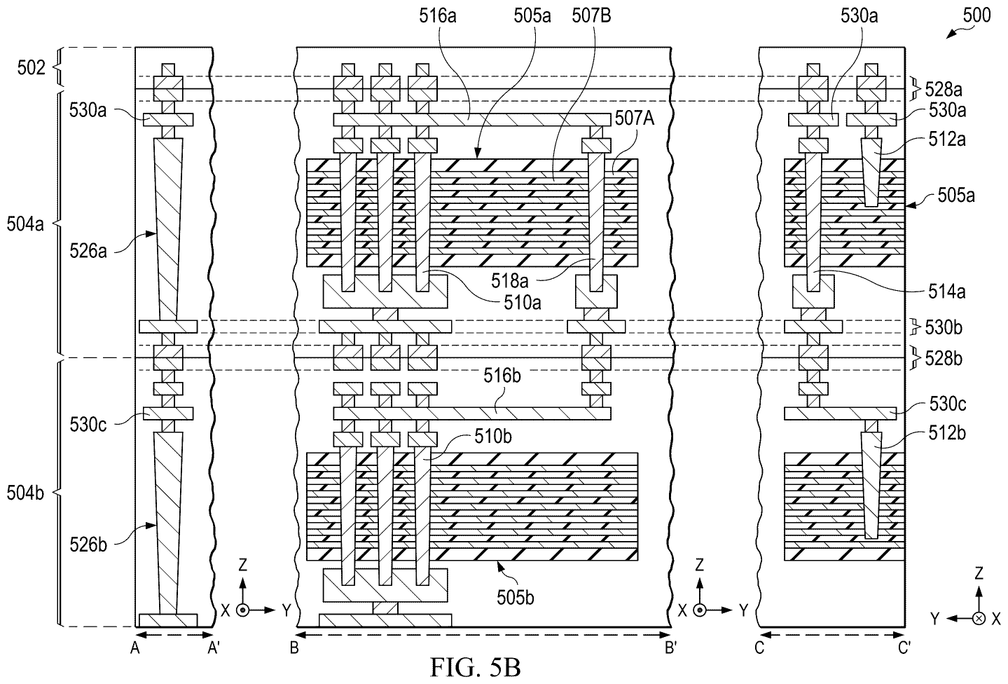

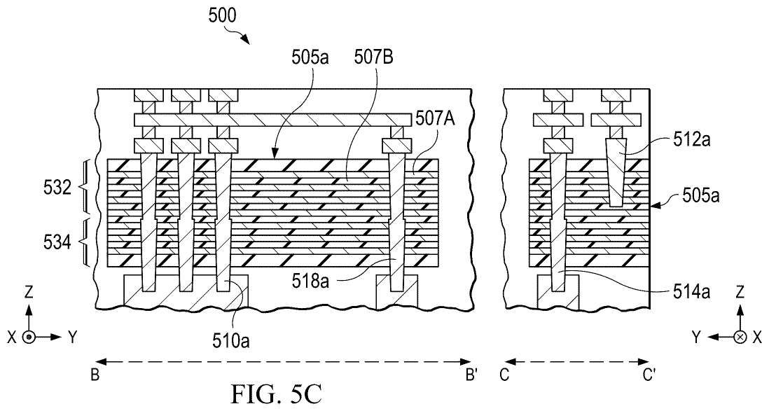

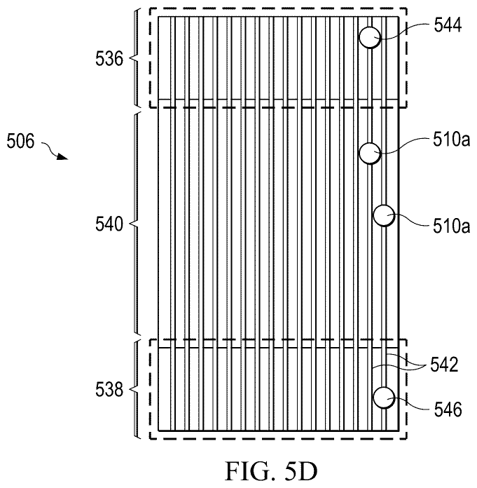

FIG. 5A illustrates a top view of an example semiconductor device 500. In some implementations, the semiconductor device 500 can be a memory device, such as an example of the 3D memory device 100 of FIG. 1. The semiconductor device 500 includes a control semiconductor structure 502 and two array semiconductor structures 504a and 504b stacked along the Z direction (e.g., as shown in FIG. 5B). FIG. 5A illustrates one of the array semiconductor structures 504a (e.g., the array semiconductor structure that is adjacent to the control semiconductor structure 502). The array semiconductor structure 504a can include one or more array regions and one or more connection regions configured to provide conductive connections for the one or more array regions. In some implementations, as shown in FIG. 5A, the array semiconductor structure 504a includes an array region 506a and a connection region 508a adjacent to the array region 506a along a horizontal direction (e.g., the X direction).

The array semiconductor structure 504a can include an array of channel structures 510a in the array region 506a. Each channel structure 510a can be used to form a string of memory cells coupled in serial along a vertical direction (e.g., Z direction) perpendicular to the horizontal direction. The array semiconductor structure 504a can include word line contact structures 512a extending along the Z direction in the connection region 508a. A word line contact structure 512a can connect a conductive layer (e.g., the conductive layer 507A in the stack 505a of FIG. 5B) in the connection region 508a to a word line (e.g., the word line 218 of FIG. 2) of the array semiconductor structure 504a. In some implementations, conductive layers in the connection region 508a can from a staircase structure (not shown), and the word line contact structures 512a can be formed on the staircase structure. In some other implementations, the conductive layers in the connection region 508a can form a structure different from a staircase structure. For example, a word line contact structure 512a can be connected to a corresponding conductive layer and can extend through other conductive layers, and spacer for insulation can be formed between the word line contact structure 512a and the other conductive layers. The array semiconductor structure 504a can also include word line connection structures 514a extending along the Z direction in the connection region 508a. In some implementations, the word line connection structures 514a of one array semiconductor structure 504a can be coupled to word line contact structures 512b of another array semiconductor structure 504b (e.g., as shown in FIG. 5B). The word line contact structures 512a and the word line connection structures 514a can be arranged in any suitable manner. For example, as shown in FIG. 5A, the word line contact structures 512a can be arranged along a first line extending in the X direction, and the word line connection structures 514a can be arranged along a second line extending in the X direction. The first line can be spaced from the second line. One of the word line contact structures 512a can be aligned with a corresponding word line connection structure 514a along the Y direction.

The array semiconductor structure 504a includes bit lines 516a extending along the Y direction in the array region 506a. Each channel structure 510a can be coupled to a respective bit line 516a. Each bit line 516a can be coupled to a respective bit line connection structure 518a extending along the Z direction in the array region 506a. The array region 506a can include a center region 520a and an edge region 522a arranged along the Y direction. The edge region 522a can be in one side of the array region 506a along the Y direction. The bit line connection structures 518a can be in the edge region 522a. The channel structures 510a can be in the center region 520a.

As shown in FIG. 5A, the array semiconductor structure 504a can include a peripheral region 524a adjacent to the array region 506a and the connection region 508a along the Y direction. The array semiconductor structure 504a can include conductive structures 526a extending along the Z direction in the peripheral region 524a. In some implementations, the center region 520a is between the edge region 522a and the peripheral region 524a along the Y direction.

It is understood that the example in FIG. 5A is for illustration purpose and is not intended to be construed in a limiting sense. In practice, any suitable arrangement of various regions in the semiconductor device 500 can be applied. In some instances, an array semiconductor structure (e.g., 504a) of the semiconductor device 500 can have two connection regions 508a and an array region 506a arranged between the two connection regions 508a along the X direction. In some other instances, the array semiconductor structure can have two array regions 506a and a connection region 508a between the two array regions 506a along the X direction.

FIG. 5B illustrates cross-sectional views of the semiconductor device 500 along cut lines AA′, BB′, and CC′ of FIG. 5A. The control semiconductor structure 502 and the array semiconductor structures 504a and 504b are stacked along the Z direction. The array semiconductor structure 504a is between the control semiconductor structure 502 and the array semiconductor structure 504b along the Z direction. The array semiconductor structure 504a includes a stack 505a of alternating conductive layers 507A and isolating layers 507B. The stack 505a can be in both the array region 506a and the connection region 508a (as shown in FIG. 5A). The stack 505a can extend in the horizontal directions (e.g., the X direction and the Y direction). The conductive layers 507A and the isolating layers 507B can alternate in the vertical direction (e.g., Z direction). The conductive layers 507A can be the same or different from each other in thickness, for example, ranging from 10-500 nm, e.g., about 35 nm. The isolating layers 507B can also be the same or different from each other in thickness, for example, ranging from 10-500 nm, e.g., about 25 nm. It should be noted that the number of the conductive layers 507A and the isolating layers 507B shown in FIG. 5B is for illustration only and that any suitable number of the conductive layers 507A and the isolating layers 507B can be included in the stack 505a. The conductive layers 507A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 507B can include a dielectric material, such as silicon oxide, silicon nitride, silicon oxynitride, or any combination thereof. In some implementations, the isolating layers 507B can also include high-K dielectric materials, such as hafnium oxide, zirconium oxide, aluminum oxide, tantalum oxide, lanthanum oxide, or any combination thereof.

In some implementations, the stack 505a includes liner layers (not shown in FIG. 5B). A liner layer can cover part or all sides of a corresponding conductive layer 507A and be between the conductive layer 507A and two isolating layers 507B adjacent to the corresponding conductive layer 507A. The liner layer can include a high-K dielectric material (e.g., Al2O3). In some examples, the conductive layer 507A includes a metallic material (e.g., W) and an adhesive material (e.g., TiN), and the adhesive material can be deposited between the metallic material and the high-K dielectric material. In some examples, the conductive layer 507A includes the metallic material (e.g., W), and the liner layer includes the adhesive material (e.g., TiN) and the high-K dielectric material.

The channel structures 510a can extend through the stack 505a along the vertical direction (e.g., the Z direction). Each channel structure 510a can be in the shape of a cylinder or a pillar, and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 507A and the isolating layers 507B of the stack 505a, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

As shown in FIG. 5B, the array semiconductor structure 504a includes the bit lines 516a being coupled to the channel structures 510a and extending along the Y direction. The bit line connection structures 518a extend through the stack 505a in the array region 506a along the vertical direction (e.g., the Z direction). The word line connection structures 514a extend through the stack 505a in the connection region 508a along the Z direction. The word line contact structures 512a extend through at least a portion of the stack 505a in the connection region 508a along the Z direction.

Although not shown in FIG. 5B, the array semiconductor structure 504b can include an array region, a connection region, and a peripheral region respectively aligned with the array region 506a, the connection region 508a, and the peripheral region 524a of the array semiconductor structure 504a along the Z direction. The array semiconductor structure 504b can include a stack 505b (which is similar to the stack 505a) of conductive layers and isolating layers alternating along the Z direction. The array semiconductor structure 504b further includes channel structures 510b extending through the stack 505b along the Z direction and bit lines 516b being coupled to the channel structures 510b and extending along the Y direction. The array semiconductor structure 504b can further include word line contact structures 512b (which are similar to the word line contact structures 512a) in its connection region and conductive structures 526b (which are similar to the conductive structures 526a) in its peripheral region.

As shown in FIG. 5B, the control semiconductor structure 502 is bonded to the array semiconductor structure 504a through a bonding structure 528a, and the array semiconductor structure 504a is bonded to the array semiconductor structure 504b through a bonding structure 528b. The bonding structures 528a and 528b can be examples of the bonding structures 106 of FIG. 1. The array semiconductor structure 504a can include an interconnect layer 530a between the bonding structure 528a and the stack 505a along the Z direction. An interconnect layer (e.g., the interconnect layer 530a and some other interconnect layers described in this disclosure) can include interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “intermetal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, W, Co, Cu, Al, silicides, or any combination thereof. The ILD layers in the interconnect layer can include dielectric materials including, but not limited to, silicon oxide, silicon nitride, silicon oxynitride, low dielectric constant (low-K) dielectrics, or any combination thereof.

The array semiconductor structure 504a can further include an interconnect layer 530b between the bonding structure 528b and the stack 505a along the Z direction. The array semiconductor structure 504b can include an interconnect layer 530c between the bonding structure 528b and the stack 505b along the Z direction. The word line contact structures 512a of the array semiconductor structure 504a are coupled to the word lines of the array semiconductor structure 504a through the interconnect layer 530a. Moreover, the word line contact structures 512a can be coupled to row decoders/word line drivers (which can include string drivers and correspond to the word lines of the array semiconductor structure 504a) in the control semiconductor structure 502 through the interconnect layer 530a and the bonding structure 528a. The word line contact structures 512b of the array semiconductor structure 504b are coupled to word lines of the array semiconductor structure 504b through the interconnect layer 530c. The word line contact structures 512b can be coupled to the word line connection structures 514a of the array semiconductor structure 504a through the interconnect layer 530c and the bonding structure 528b. In some implementations, one of the word line connection structures 514a is coupled to a corresponding word line contact structure 512b. The word line connection structures 514a can be coupled to row decoders/word line drivers (which can include string drivers and correspond to the word lines of the array semiconductor structure 504b) in the control semiconductor structure 502 through the interconnect layer 530a and the bonding structure 528a. In some implementations, as shown in FIG. 5B, one of the word line contact structures 512a can be aligned with a corresponding word line contact structure 512b along the Z direction.

In some implementations, the bit lines 516a of the array semiconductor structure 504a and the bit lines 516b of the array semiconductor structure 504b can share a same page buffer (e.g., the page buffer 304 of FIGS. 3-4) in the control semiconductor structure 502. For example, the bit lines 516a can be coupled to the page buffer (that correspond to the bit lines 516a and 516b) in the control semiconductor structure 502 through the bonding structure 528a. In addition, the bit lines 516a can be coupled to the bit lines 516b through the bit line connection structures 518a, the interconnect layer 530b, and the bonding structure 528b. In some implementations, one of the bit line connection structures 518a is coupled to a corresponding bit line 516a and a corresponding bit line 516b, and the corresponding bit line 516a and the corresponding bit line 516b are aligned along the Z direction. The corresponding bit line 516a and the corresponding bit line 516b can be coupled to one of page buffer circuits (e.g., the page buffer circuits 402 of FIG. 4) of the page buffer. In some implementations, the bit lines 516a can be coupled to the bit line connection structures 518a through an interconnect layer, which may or may not be the same as the interconnect layer 530a.

The conductive structures 526a can be coupled to the control semiconductor structure 502 through the interconnect layer 530a and the bonding structure 528a. The conductive structures 526b can be coupled to the conductive structures 526a through the interconnect layer 530c, the bonding structure 528b, and the interconnect layer 530b. Each conductive structure 526a can be aligned with a corresponding conductive structure 526b along the Z direction. In some implementations, the conductive structures 526a can include or can be coupled to a seal ring, an array common source, or other conductive contacts in the peripheral region 524a. In some implementations, the conductive structures 526a can include at least one of a part of conductive contacts of the bonding structure 528a, a part of interconnects of the interconnect layer 530a, a part of interconnects of the interconnect layer 530b, or a part of conductive contacts of the bonding structure 528b, and can extend through the array semiconductor structure 504a in the peripheral region 524a along the Z direction. Similarly, the conductive structures 526b can include or can be coupled to a seal ring, an array common source, or other conductive contacts in the peripheral region of the array semiconductor structure 504b. In some implementations, the conductive structures 526b can include at least one of a part of conductive contacts of the bonding structure 528b or a part of interconnects of the interconnect layer 530c, and can extend through the array semiconductor structure 504b in its peripheral region along the Z direction.

In some implementations, as shown in FIG. 5C, the stack 505a of the array semiconductor structure 504a can include multiple decks (e.g., decks 532 and 534) stacked along the vertical direction (e.g., the Z direction). Each of the multiple decks can include a subset of the conductive layers 507A and the isolating layers 507B in the stack 505a. Each of the channel structures 510a, the bit line connection structures 518a, and the word line connection structures 514a that extend through the stack 505a can have multiple portions sequentially connected along the Z direction. Each portion can extend through a respective deck of the stack 505a and can have a size gradually reducing along the vertical direction (e.g., the Z direction). For example, as shown in FIG. 5C, the bit line connection structure 518a can have an upper portion and a lower portion connected at the interface between the deck 532 and the deck 534. Similarly, the stack 505b of the array semiconductor structure 504b can include multiple decks. Each of the channel structures 510b can have multiple portions sequentially connected along the Z direction. Each portion of the channel structure 510b can extend through a respective deck of the stack 505b and can have a size gradually reducing along the vertical direction (e.g., the Z direction). It is understood that FIG. 5C is for illustration purpose and in practice, any suitable number of decks can be applied to the stack 505a or the stack 505b.

In some implementations, as shown in FIG. 5D, an array semiconductor structure (e.g., the array semiconductor structure 504a or 504b of FIG. 5B) can have an array region 506 including two edge regions 536 and 538 and a center region 540 arranged along the Y direction. The edge region 536 and the edge region 538 are in two opposite sides of the array region 506 along the Y direction. The center region 540 is between the edge regions 536 and 538 along the Y direction. In this example, the array semiconductor structure includes bit lines 542 extending along the Y direction in the edge regions 536 and 538 and the center region 540. The array semiconductor structure includes a first set of bit line connection structures 544 in the edge region 536 and a second set of bit line connection structures 546 in the edge region 538. The edge region 538 can be between the center region 540 and a peripheral region (e.g., the peripheral region 524a of FIG. 5A) of the array semiconductor structure along the Y direction.

The bit line connection structures (e.g., 518a), the word line connection structures (e.g., 514a), and the word line contact structures (e.g., 512a and 512b) can include any suitable conducting material, such as W, Co, Cu, Al, TiN, polysilicon, doped silicon, silicides, or any combination thereof. In some implementations, each of these connection or contact structures can include an outer layer and an inner structure surrounded by the outer layer. The inner structure can include any suitable conductive material, and the outer layer can include any suitable dielectric material (e.g., silicon oxide).

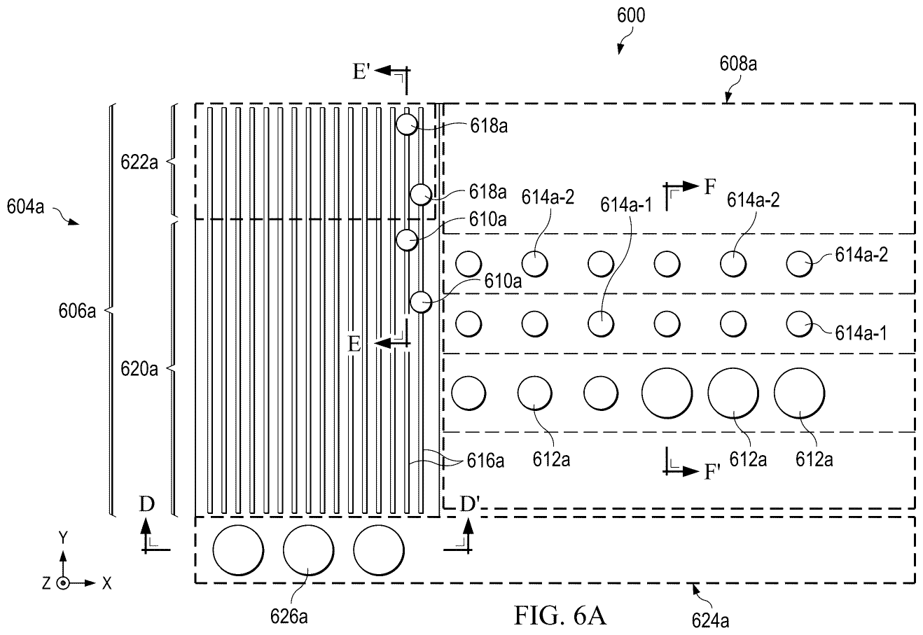

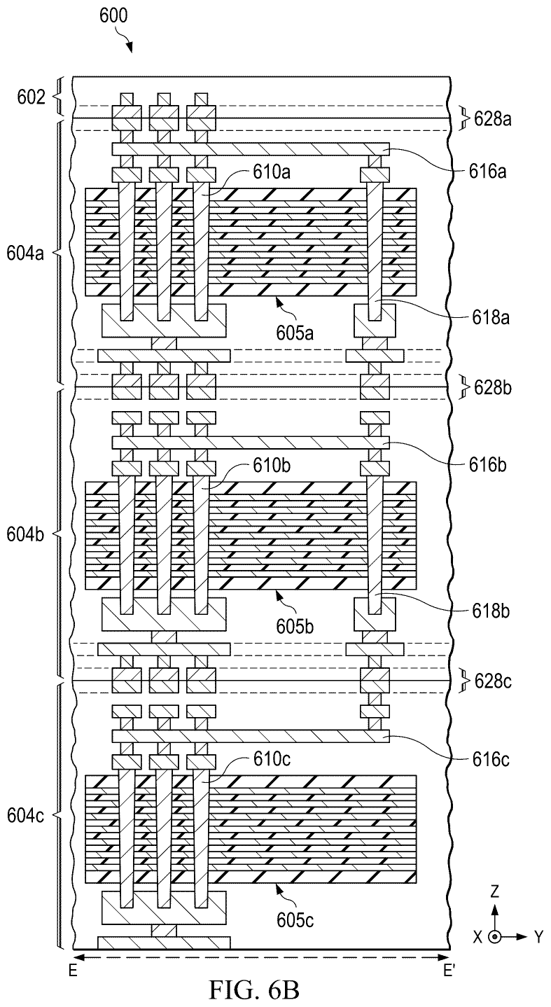

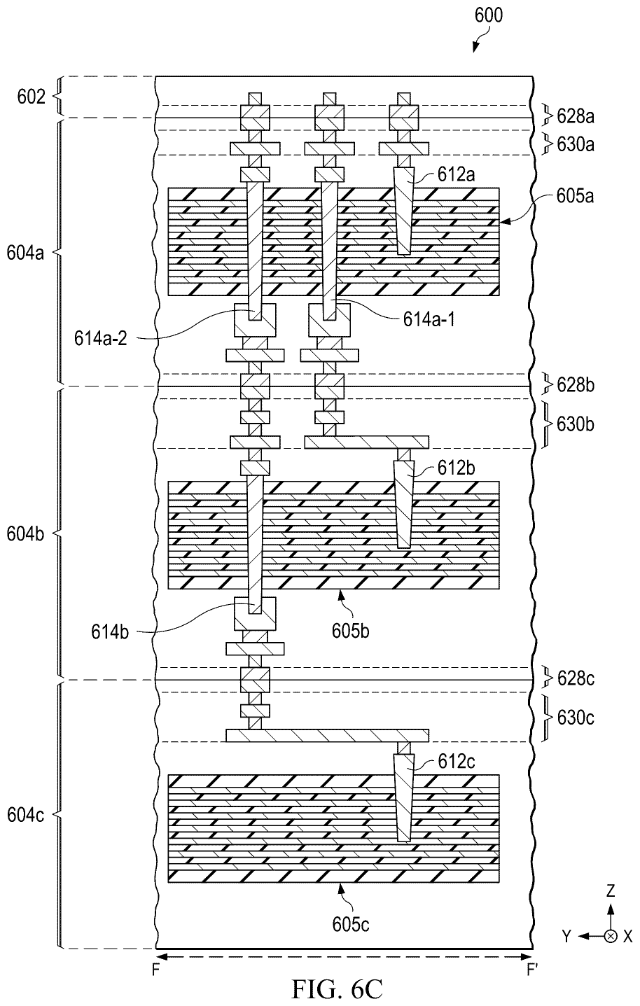

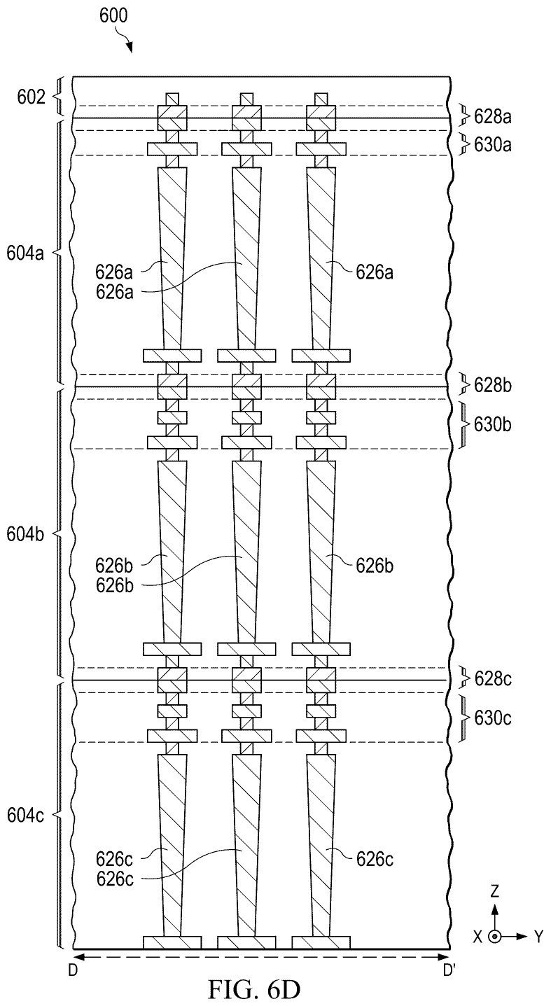

FIG. 6A illustrates a top view of an example semiconductor device 600. In some implementations, the semiconductor device 600 can be a memory device, such as an example of the 3D memory device 100 of FIG. 1. The semiconductor device 600 includes a control semiconductor structure 602 and three array semiconductor structures 604a, 604b, and 604c stacked along the Z direction (e.g., as shown in FIGS. 6B-6D). FIG. 6A illustrates one of the array semiconductor structures 604a (e.g., the array semiconductor structure that is adjacent to the control semiconductor structure 602). The array semiconductor structure 604a can be similar to the array semiconductor structure 504a of FIGS. 5A-5B. The array semiconductor structure 604a can include an array region 606a (similar to the array region 506a of FIG. 5A), a connection region 608a (similar to the connection region 508a of FIG. 5A), and a peripheral region 624a (similar to the peripheral region 524a of FIG. 5A). The array semiconductor structure 604a can include an array of channel structures 610a (similar to the channel structures 510a of FIGS. 5A-5B) in the array region 606a. The array semiconductor structure 604a can include word line contact structures 612a extending along the Z direction in the connection region 608a. A word line contact structure 612a can connect a conductive layer (e.g., the conductive layer 607A in the stack 605a of FIG. 6B) in the connection region 608a to a word line (e.g., the word line 218 of FIG. 2) of the array semiconductor structure 604a. The array semiconductor structure 604a can also include a group of word line connection structures 614a-1 and a group of word line connection structures 614a-2 extending along the Z direction in the connection region 608a. In some implementations, e.g., as shown in FIG. 6D, the group of word line connection structures 614a-1 can be coupled to word line contact structures 612b of another array semiconductor structure 604b, and the group of word line connection structures 614a-2 can be coupled to word line contact structures 612c of another array semiconductor structure 604c.

The word line contact structures 612a and the word line connection structures 614a-1 and 614a-2 can be arranged in any suitable manner. For example, as shown in FIG. 6A, the word line contact structures 612a can be arranged along a first line extending in the X direction, the word line connection structures 614a-1 can be arranged along a second line extending in the X direction, and the word line connection structures 614a-2 can be arranged along a third line extending in the X direction. The first line, the second line, and the third lines can be spaced from each other along the Y direction. One of the word line contact structures 612a can be aligned with a corresponding word line connection structure 614a-1 and a corresponding word line connection structure 614a-2 along the Y direction.

The array semiconductor structure 604a includes bit lines 616a extending along the Y direction in the array region 606a. Each channel structure 610a can be coupled to a respective bit line 616a. Each bit line 616a can be coupled to a respective bit line connection structure 618a extending along the Z direction in the array region 606a. The array region 606a can include a center region 620a and an edge region 622a arranged along the Y direction. The edge region 622a can be in one side of the array region 606a along the Y direction. The bit line connection structures 618a can be in the edge region 622a. The channel structures 610a can be in the center region 620a.

As shown in FIG. 6A, the array semiconductor structure 604a can include conductive structures 626a extending along the Z direction in the peripheral region 624a. In some implementations, the center region 620a is between the edge region 622a and the peripheral region 624a along the Y direction.

FIGS. 6B-6D illustrate cross-sectional views of the semiconductor device 600 along cut lines DD′, EE′, and FF′ of FIG. 6A, respectively. The control semiconductor structure 602 and the array semiconductor structures 604a, 604b, and 604c are stacked along the Z direction. Although not shown in FIGS. 6A-6D, the array semiconductor structure 604b can include an array region 606b, a connection region 608b, and a peripheral region 624b respectively aligned with the array region 606a, the connection region 608a, and the peripheral region 624a of the array semiconductor structure 604a along the Z direction. Similarly, the array semiconductor structure 604c can include an array region 606c, a connection region 608c, and a peripheral region 624c respectively aligned with the array region 606a, the connection region 608a, and the peripheral region 624a along the Z direction. The control semiconductor structure 602 is bonded to the array semiconductor structure 604a through a bonding structure 628a, the array semiconductor structure 604a is bonded to the array semiconductor structure 604b through a bonding structure 628b, and the array semiconductor structure 604b is bonded to the array semiconductor structure 604c through a bonding structure 628c. The bonding structures 628a, 628b, and 628c can be similar to, or same as the bonding structures 106 of FIG. 1 or the bonding structures 528a and 528b of FIG. 5B.

As shown in FIG. 6B, each of the array semiconductor structures 604a, 604b, and 604c includes a stack (e.g., stacks 605a, 605b, and 605c) of alternating conductive layers and isolating layers. The stacks 605a, 605b, and 605c can be similar to, or same as the stack 505a or 505b of FIG. 5B. In addition, each of the array semiconductor structures 604a, 604b, and 604c includes channel structures (e.g., channel structures 610a, 610b, and 610c) extending through its respective stack along the Z direction. The channel structures 610a, 610b, and 610c can be similar to, or same as the channel structures 510a or 510b of FIGS. 5A-5B.

The array semiconductor structure 604a includes the bit lines 616a being coupled to the channel structures 610a and extending along the Y direction. The array semiconductor structure 604b includes the bit lines 616b being coupled to the channel structures 610b and extending along the Y direction. The array semiconductor structure 604c includes the bit lines 616c being coupled to the channel structures 610c and extending along the Y direction. The array semiconductor structure 604a includes the bit line connection structures 618a extending through the stack 605a in the array region 606a along the Z direction. The array semiconductor structure 604b includes the bit line connection structures 618b extending through the stack 605b in the array region 606b along the Z direction.

In some implementations, the bit lines 616a, 616b, and 616c can share a same page buffer (e.g., the page buffer 304 of FIGS. 3-4) in the control semiconductor structure 602. For example, the bit lines 616a can be coupled to the page buffer in the control semiconductor structure 602 through the bonding structure 628a. The bit lines 616a can be coupled to the bit lines 616b through the bit line connection structures 618a and the bonding structure 528b. The bit lines 616b can be coupled to the bit lines 616c through the bit line connection structures 618b and the bonding structure 628c. In some implementations, one of the bit line connection structures 618a is coupled to a corresponding bit line 616a, a corresponding bit line 616b, a corresponding bit line connection structure 618b, and a corresponding bit line 616c. The corresponding bit line 616a, the corresponding bit line 616b, and the corresponding bit line 616c are aligned along the Z direction. The corresponding bit line 616a, the corresponding bit line 616b, and the corresponding bit line 616c can be coupled to one of page buffer circuits (e.g., the page buffer circuits 402 of FIG. 4) of the page buffer. In some implementations, the bit lines 616a can be coupled to the bit line connection structures 618a through an interconnect layer of the array semiconductor structure 604a, and the bit lines 616b can be coupled to the bit line connection structures 618b through an interconnect layer of the array semiconductor structure 604b.

As shown in FIG. 6C, the array semiconductor structure 604a includes the word line contact structures 612a and the word line connection structures 614a-1 and 614a-2. The word line contact structures 612a extend through at least a portion of the stack 605a in the connection region 608a along the Z direction. The word line connection structures 614a-1 and 614a-2 extend through the stack 605a in the connection region 608a along the Z direction. The array semiconductor structure 604a can include an interconnect layer 630a between the bonding structure 628a and the stack 605a along the Z direction. The array semiconductor structure 604b includes word line contact structures 612b and word line connection structures 614b. The word line contact structures 612b extend through at least a portion of the stack 605b in the connection region 608b along the Z direction. The word line connection structures 614b extend through the stack 605b in the connection region 608b along the Z direction. The array semiconductor structure 604b can include an interconnect layer 630b between the bonding structure 628b and the stack 605b along the Z direction. The array semiconductor structure 604c includes word line contact structures 612c extending through at least a portion of the stack 605c in the connection region 608c along the Z direction. The array semiconductor structure 604c can include an interconnect layer 630c between the bonding structure 628c and the stack 605c along the Z direction. In the example of FIG. 6C, one of the word line contact structures 612a is aligned with a corresponding word line contact structure 612b and a corresponding word line contact structure 612c along the Z direction. One of the word line connection structures 614a-2 can be aligned with a corresponding word line connection structure 614b along the Z direction. In some implementations, a quantity of the word line connection structures 614a-1 and 614a-2 is equal to or greater than a sum of a quantity of the word line contact structures 612b and a quantity of the word line contact structures 612c.

The word line contact structures 612a can be coupled to the word lines of the array semiconductor structure 604a through the interconnect layer 630a. Moreover, the word line contact structures 612a can be coupled to row decoders/word line drivers (which can include string drivers and correspond to the word lines of the array semiconductor structure 604a) in the control semiconductor structure 602 through the interconnect layer 630a and the bonding structure 628a. The word line contact structures 612b can be coupled to word lines of the array semiconductor structure 604b through the interconnect layer 630b. The word line contact structures 612b can be coupled to the word line connection structures 614a-1 of the array semiconductor structure 604a through the interconnect layer 630b and the bonding structure 628b. In some implementations, one of the word line connection structures 614a-1 is coupled to a corresponding word line contact structure 612b. The word line connection structures 614a-1 can be coupled to row decoders/word line drivers (which can include string drivers and correspond to the word lines of the array semiconductor structure 604b) in the control semiconductor structure 602 through the interconnect layer 630a and the bonding structure 628a. The word line contact structures 612c can be coupled to word lines of the array semiconductor structure 604c through the interconnect layer 630c. The word line contact structures 612c can be coupled to the word line connection structures 614b of the array semiconductor structure 604b through the interconnect layer 630c and the bonding structure 628c. The word line connection structures 614b can be coupled to the word line connection structures 614a-2 of the array semiconductor structure 604a through the interconnect layer 630b and the bonding structure 628b. In some implementations, one of the word line connection structures 614a-2 is coupled to a corresponding word line contact structure 612c through a corresponding word line connection structure 614b. The word line connection structures 614a-2 can be coupled to row decoders/word line drivers (which can include string drivers and correspond to the word lines of the array semiconductor structure 604bc) in the control semiconductor structure 602 through the interconnect layer 630a and the bonding structure 628a.

As shown in FIG. 6D, the conductive structures 626a can be coupled to the control semiconductor structure 602 through the interconnect layer 630a and the bonding structure 628a. The conductive structures 626a can be coupled to conductive structures 626b in the peripheral region 624b of the array semiconductor structure 604b through the bonding structure 628b and the interconnect layer 630b. The conductive structures 626b can be coupled to conductive structures 626c in the peripheral region 624c of the array semiconductor structure 604c through the bonding structure 628c and the interconnect layer 630c. In some implementations, each conductive structure 626a can be aligned with a corresponding conductive structure 626b and a corresponding conductive structure 626c along the Z direction. In some implementations, the conductive structures 626a can include or can be coupled to a seal ring, an array common source, or other conductive contacts in the peripheral region 624a of the array semiconductor structure 604a. In some implementations, the conductive structures 626a can include at least one of a part of conductive contacts of the bonding structure 628a or a part of interconnects of the interconnect layer 630a, or a part of conductive contacts of the bonding structure 628b, and can extend through the array semiconductor structure 604a in the peripheral region 624a along the Z direction. Similarly, the conductive structures 626b can include or can be coupled to a seal ring, an array common source, or other conductive contacts in the peripheral region 624b of the array semiconductor structure 604b. In some implementations, the conductive structures 626b can include at least one of a part of conductive contacts of the bonding structure 628b, a part of interconnects of the interconnect layer 630b, or a part of conductive contacts of the bonding structure 628c, and can extend through the array semiconductor structure 604b in the peripheral region 624b along the Z direction. The conductive structures 626c can include or can be coupled to a seal ring, an array common source, or other conductive contacts in the peripheral region 624c of the array semiconductor structure 604c. In some implementations, the conductive structures 626c can include at least one of a part of conductive contacts of the bonding structure 628c or a part of interconnects of the interconnect layer 630c, and can extend through the array semiconductor structure 604c in the peripheral region 624c along the Z direction.

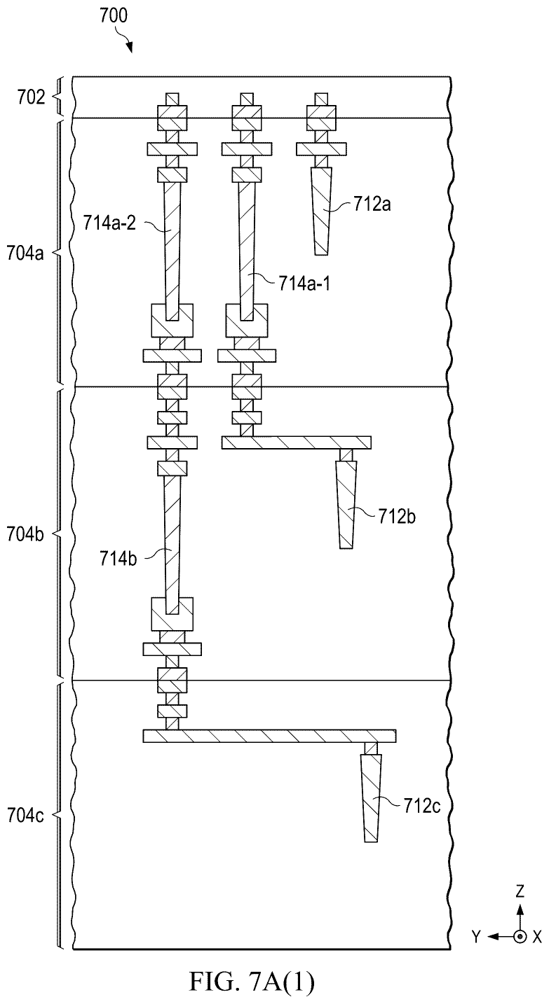

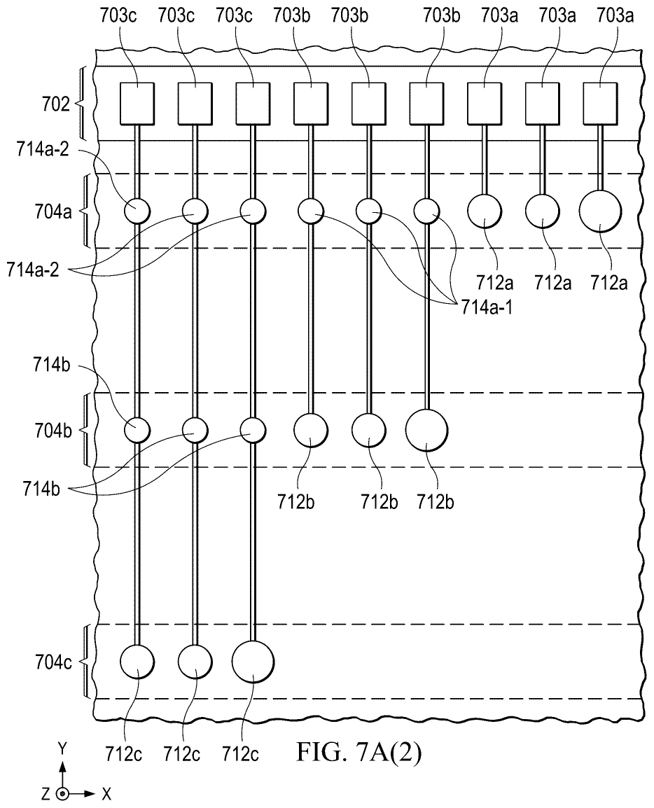

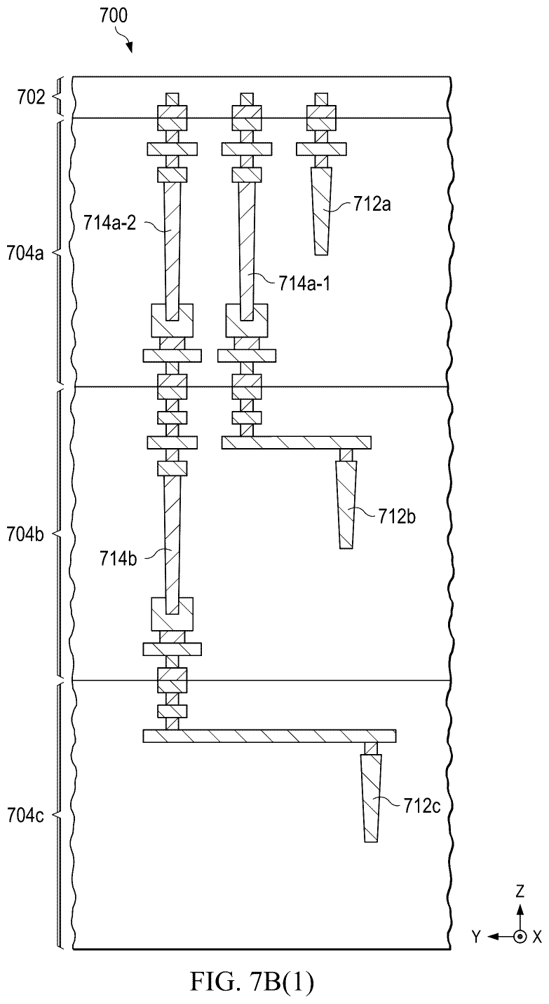

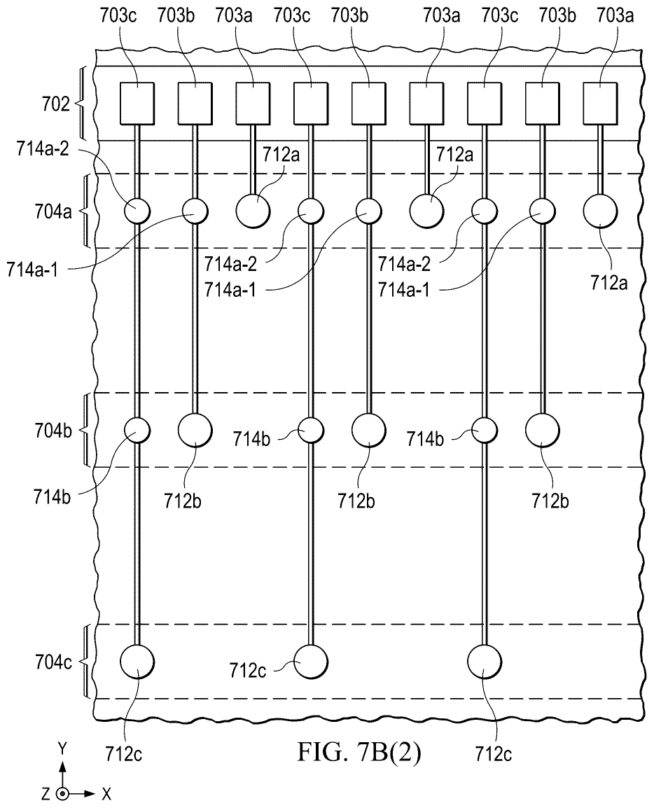

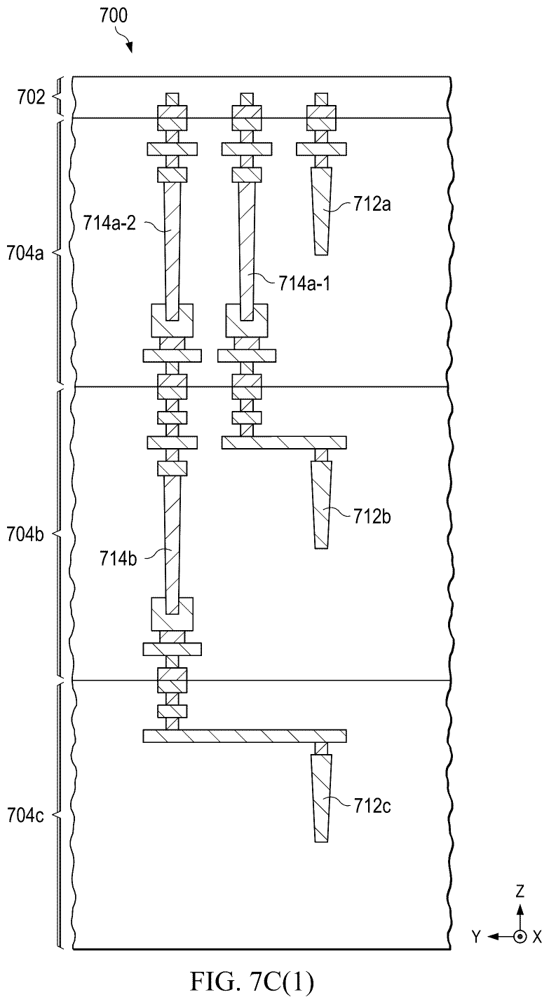

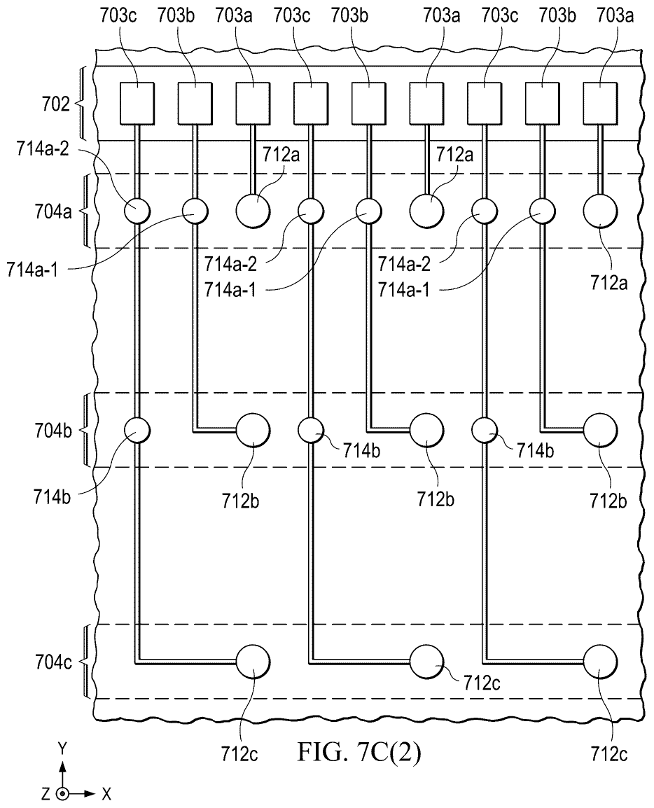

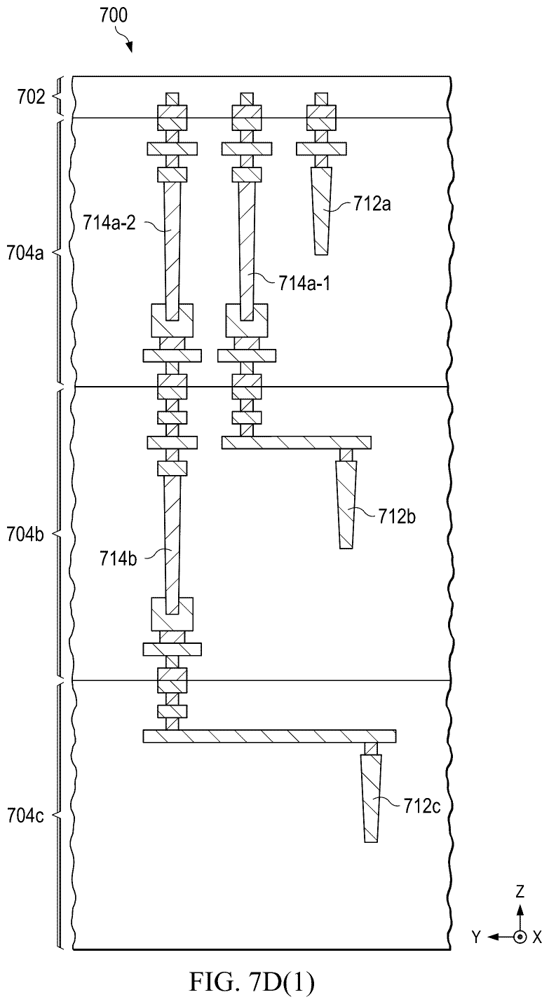

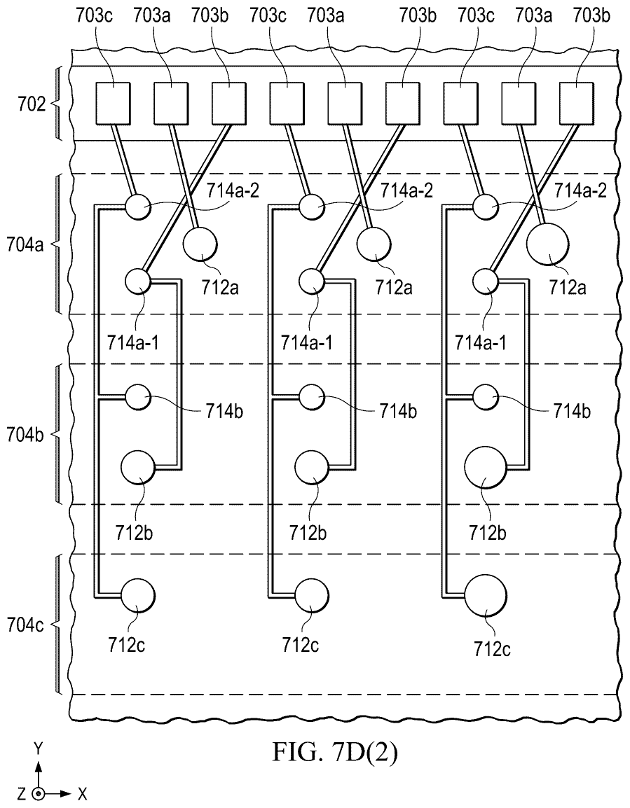

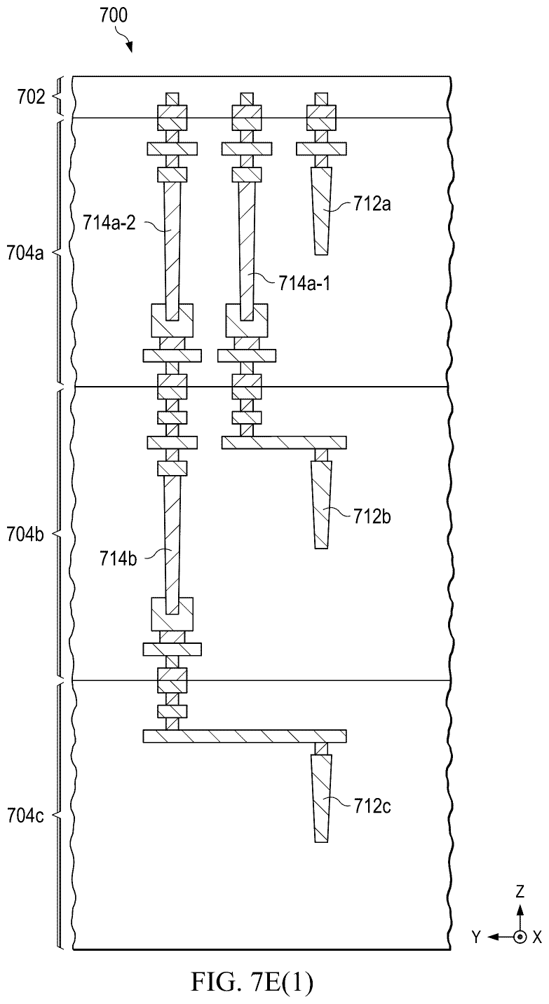

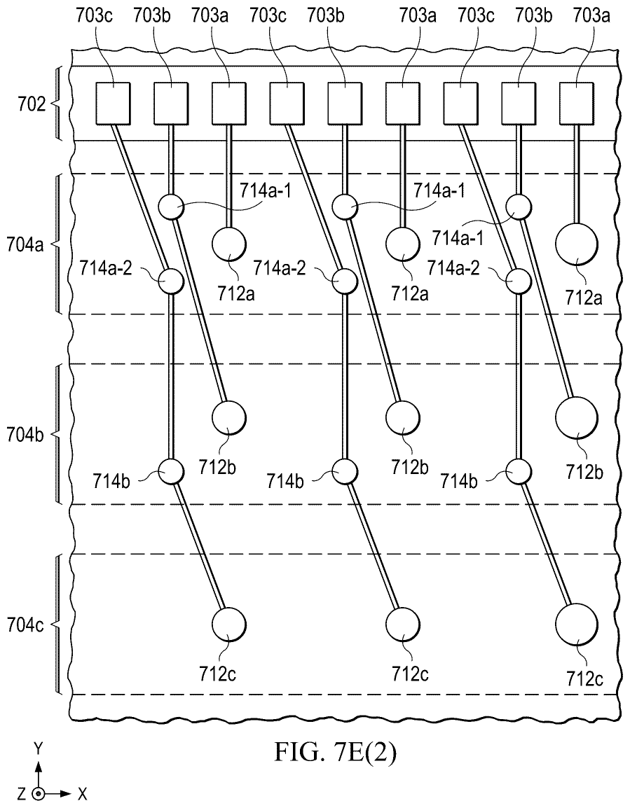

FIGS. 7A (1)-7E (2) illustrate an example semiconductor device 700 having word line contact structures and word line connection structures arranged in various ways. The semiconductor device 700 can be a memory device, such as an example of the 3D memory device 100 of FIG. 1. In some implementations, the semiconductor device 700 can be similar to the semiconductor device 600 of FIGS. 6A-6D. For example, the semiconductor device 700 includes a control semiconductor structure 702 (similar to the control semiconductor structure 602 of FIG. 6C), an array semiconductor structure 704a (similar to the array semiconductor structure 604a of FIG. 6C), an array semiconductor structures 704b (similar to the array semiconductor structure 604b of FIG. 6C), and an array semiconductor structures 704c (similar to the array semiconductor structure 604c of FIG. 6C) stacked along the Z direction. The array semiconductor structure 704a includes word line contact structures 712a (similar to the word line contact structures 612a of FIG. 6C) and word line connection structures 714a-1 and 714a-2 (similar to the word line connection structures 614a-1 and 614a-2 of FIG. 6C) extending along the Z direction. The array semiconductor structure 704b includes word line contact structures 712b (similar to the word line contact structures 612b of FIG. 6C) and word line connection structures 714b (similar to the word line connection structures 614b of FIG. 6C) extending along the Z direction. The array semiconductor structure 704c includes word line contact structures 712c (similar to the word line contact structures 612c of FIG. 6C) extending along the Z direction. As shown in FIGS. 7A (2)-7E (2), the word line contact structures 712a can be coupled to row decoders/word line drivers 703a (which can include string drivers as shown in FIG. 4) in the control semiconductor structure 702. For example, each word line contact structure 712a is coupled to a corresponding row decoder/word line driver 703a. The word line contact structures 712b can be coupled to row decoders/word line drivers 703b in the control semiconductor structure 702 through the word line connection structures 714a-1. For example, each word line contact structure 712b is coupled to a corresponding row decoder/word line driver 703b through a corresponding word line connection structure 714a-1. The word line contact structures 712c can be coupled to row decoders/word line drivers 703c in the control semiconductor structure 702 through the word line connection structures 714b and 714a-2. For example, each word line contact structure 712c is coupled to a corresponding row decoder/word line driver 703c through a corresponding word line connection structure 714b and a corresponding word line connection structure 714a-2.

FIGS. 7A (1)-7A (2) illustrate an example arrangement of the word line contact structures and the word line connection structures in the semiconductor device 700. FIG. 7A (1) shows a side view of the semiconductor device 700, and FIG. 7A (2) shows top view of each semiconductor structure of the semiconductor device 700. It is understood that connection lines in FIG. 7A (2) indicate two or more components being coupled together and may or may not reflect locations of actual wires or interconnects between the two or more components. The same notion for describing the coupling relationships is also applied to other figures such as FIG. 7B (2), FIG. 7C (2), FIG. 7D (2), and FIG. 7E (2).

As shown in FIG. 7A (2), in the array semiconductor structure 704a, the word line connection structures 714a-1 and 714a-2 and the word line contact structures 712a are arranged along a line extending in the X direction. The word line connection structures 714a-2 are disposed next to and spaced from each other. The word line connection structures 714a-1 are disposed next to and spaced from each other. The word line contact structures 712a are disposed next to and spaced from each other. In the array semiconductor structure 704b, the word line connection structures 714b and the word line contact structures 712b are arranged along a line extending in the X direction. The word line connection structures 714b are disposed next to and spaced from each other. The word line contact structures 712b are disposed next to and spaced from each other. In the array semiconductor structure 704c, the word line contact structures 712c are arranged along a line extending in the X direction. The word line contact structures 712c are disposed next to and spaced from each other. In some implementations, each word line contact structure 712b can be aligned with a corresponding word line connection structure 714a-1 along the Z direction. Each word line contact structure 712c can be aligned with a corresponding word line connection structure 714b and a corresponding word line connection structure 714a-2 along the Z direction.

FIGS. 7B (1)-7B (2) illustrate another example arrangement of the word line contact structures and the word line connection structures in the semiconductor device 700. As shown in FIG. 7B (2), in the array semiconductor structure 704a, the word line connection structures 714a-1 and 714a-2 and the word line contact structures 712a are arranged along a line extending in the X direction. The word line connection structures 714a-1 and 714a-2 and the word line contact structures 712a can alternate with each other along the X direction. For example, each word line connection structure 714a-1 is disposed next to and spaced from a corresponding word line contact structure 712a, and each word line connection structure 714a-2 is disposed next to and spaced from a corresponding word line connection structure 714a-1. In the array semiconductor structure 704b, the word line connection structures 714b and the word line contact structures 712b are arranged along a line extending in the X direction. The word line connection structures 714b and the word line contact structures 712b can alternate with each other along the X direction. For example, each word line connection structure 714b is disposed next to and spaced from a corresponding word line contact structure 712b. In the array semiconductor structure 704c, the word line contact structures 712c are arranged along a line extending in the X direction. In some implementations, each word line contact structure 712b can be aligned with a corresponding word line connection structure 714a-1 along the Z direction. Each word line contact structure 712c can be aligned with a corresponding word line connection structure 714b and a corresponding word line connection structure 714a-2 along the Z direction.

FIGS. 7C (1)-7C (2) illustrate another example arrangement of the word line contact structures and the word line connection structures in the semiconductor device 700. As shown in FIG. 7C (2), in the array semiconductor structure 704a, the word line connection structures 714a-1 and 714a-2 and the word line contact structures 712a are arranged along a line extending in the X direction. The word line connection structures 714a-1 and 714a-2 and the word line contact structures 712a can alternate with each other along the X direction. For example, each word line connection structure 714a-1 is disposed next to and spaced from a corresponding word line contact structure 712a, and each word line connection structure 714a-2 is disposed next to and spaced from a corresponding word line connection structure 714a-1. In the array semiconductor structure 704b, the word line connection structures 714b and the word line contact structures 712b are arranged along a line extending in the X direction. The word line connection structures 714b and the word line contact structures 712b can alternate with each other along the X direction. For example, each word line connection structure 714b is disposed next to and spaced from a corresponding word line contact structure 712b. In the array semiconductor structure 704c, the word line contact structures 712c are arranged along a line extending in the X direction. In some implementations, each word line contact structure 712a can be aligned with a corresponding word line contact structure 712b and a corresponding word line contact structure 712c along the Z direction. A word line connection structure 714a-2 and a word line connection structure 714b that are coupled to the same word line contact structure 712c can be aligned along the Z direction.

FIGS. 7D (1)-7D (2) illustrate another example arrangement of the word line contact structures and the word line connection structures in the semiconductor device 700. As shown in FIG. 7D (2), in the array semiconductor structure 704a, the word line connection structures 714a-2 are arranged along a first line extending in the X direction, the word line connection structures 714a-1 are arranged along a second line extending in the X direction, and the word line contact structures 712a are arranged along a third line extending in the X direction. The first line, the second line, and the third line are spaced from each other along the Y direction. The third line is between the first line and the second line along the Y direction. In some implementations, each word line connection structure 714a-1 is aligned with a corresponding word line connection structure 714a-2 along the Y direction. The word line connection structures 714a-1 may not be aligned with the word line contact structures 712a along the Y direction. For example, a word line contact structure 712a can be disposed between two adjacent word line connection structures 714a-1 along the X direction. In the array semiconductor structure 704b, the word line connection structures 714b are arranged along a fourth line extending in the X direction, and the word line contact structures 712b are arranged along a fifth line extending in the X direction. The fourth line and the fifth line are spaced from each other along the Y direction. In some implementations, each word line connection structure 714b is aligned with a corresponding word line contact structure 712b along the Y direction. In the array semiconductor structure 704c, the word line contact structures 712c are arranged along a sixth line extending in the X direction. In some implementations, each word line contact structure 712b is aligned with a corresponding word line connection structure 714a-1 along the Z direction. Each word line contact structure 712c can be aligned with a corresponding word line connection structure 714b and a corresponding word line connection structure 714a-2 along the Z direction.

FIGS. 7E (1)-7E (2) illustrate another example arrangement of the word line contact structures and the word line connection structures in the semiconductor device 700. As shown in FIG. 7E (2), in the array semiconductor structure 704a, the word line connection structures 714a-2 are arranged along a first line extending in the X direction, the word line connection structures 714a-1 are arranged along a second line extending in the X direction, and the word line contact structures 712a are arranged along a third line extending in the X direction. The first line, the second line, and the third line are spaced from each other along the Y direction. The third line is between the first line and the second line along the Y direction. In some implementations, each word line connection structure 714a-1 is aligned with a corresponding word line connection structure 714a-2 along the Y direction. The word line connection structures 714a-1 may not be aligned with the word line contact structures 712a along the Y direction. For example, a word line contact structure 712a can be disposed between two adjacent word line connection structures 714a-1 along the X direction. In the array semiconductor structure 704b, the word line connection structures 714b are arranged along a fourth line extending in the X direction, and the word line contact structures 712b are arranged along a fifth line extending in the X direction. The fourth line and the fifth line are spaced from each other along the Y direction. In some implementations, the word line connection structures 714b may not be aligned with the word line contact structures 712b along the Y direction. In the array semiconductor structure 704c, the word line contact structures 712c are arranged along a sixth line extending in the X direction. In some implementations, each word line contact structure 712a is aligned with a corresponding word line contact structure 712b and a corresponding word line contact structure 712c along the Z direction. In some implementations, each word line connection structure 714a-2 can be aligned with a corresponding word line connection structure 714b along the Z direction.

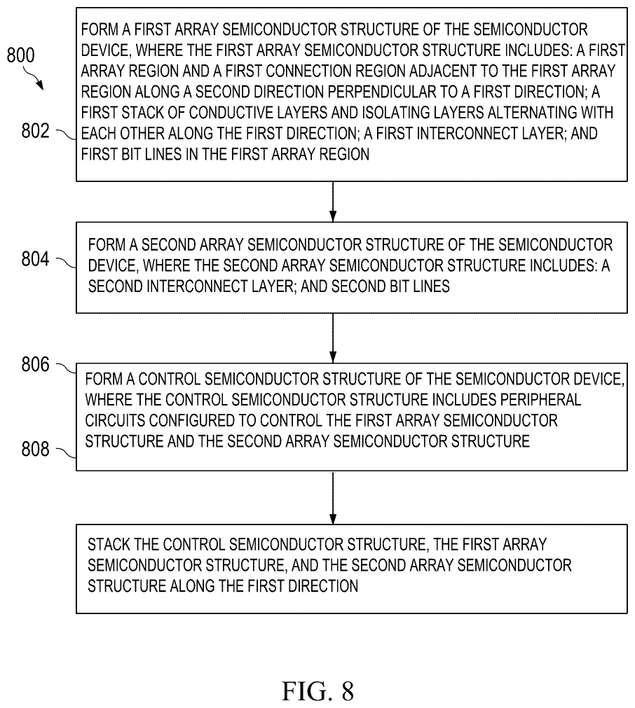

FIG. 8 illustrates a flow chart of an example process 800. The process 800 can be performed to form a semiconductor device, such as the semiconductor device 100 illustrated by FIG. 1, the semiconductor device 500 illustrated by FIGS. 5A-5D, the semiconductor device 600 illustrated by FIGS. 6A-6D, or the semiconductor device 700 illustrated by FIGS. 7A (1)-7E (2). It is understood that the operations shown in process 800 are not exhaustive and that other operations can be performed as well before, after, or between any of the illustrated operations. Further, some of the operations may be performed simultaneously, or in a different order than as shown in FIG. 8.

At operation 802, a first array semiconductor structure (e.g., the array semiconductor structure 504a of FIGS. 5A-5B) of the semiconductor device (e.g., the semiconductor device 500 of FIGS. 5A-5C) is formed. The first array semiconductor structure can include a first array region (e.g., the array region 506a of FIG. 5A) and a first connection region (e.g., the connection region 508a of FIG. 5A) adjacent to the first array region along a second direction (e.g., the X direction) perpendicular to a first direction (e.g., the Z direction). The first array semiconductor structure can further include: a first stack (e.g., the stack 505a of FIG. 5B) of conductive layers and isolating layers alternating with each other along the first direction; a first interconnect layer (e.g., the interconnect layer 530a of FIG. 5B); and first bit lines (e.g., the bit lines 516a of FIGS. 5A-5B) in the first array region.

At operation 804, a second array semiconductor structure (e.g., the array semiconductor structure 504b of FIG. 5B) of the semiconductor device is formed. The second array semiconductor structure can include a second interconnect layer (e.g., the interconnect layer 530c of FIG. 5B) and second bit lines (e.g., the bit lines 516b of FIG. 5B).

At operation 806, a control semiconductor structure (e.g., the control semiconductor structure 502 of FIG. 5B) of the semiconductor device is formed. The control semiconductor structure can include peripheral circuits (e.g., the peripheral circuits 202 of FIG. 3) configured to control the first array semiconductor structure and the second array semiconductor structure.

At operation 808, the control semiconductor structure, the first array semiconductor structure, and the second array semiconductor structure are stacked along the first direction (e.g., as shown in FIG. 5B).

In some implementations, the process 800 further includes bonding the control semiconductor structure to the first array semiconductor structure using a first bonding structure (e.g., the bonding structure 528a of FIG. 5B). The process 800 further includes bonding the first array semiconductor structure to the second array semiconductor structure using a second bonding structure (e.g., the bonding structure 528b of FIG. 5B).

In some implementations, forming the first array semiconductor structure includes forming first bit line connection structures (e.g., the bit line connection structures 518a of FIG. 5B) in the first array region. The first bit line connection structures are coupled to the first bit lines and extend through the first stack along the first direction. The first bit line connection structures are coupled to the second bit lines. Forming the first array semiconductor structure further includes forming first word line contact structures (e.g., the word line contact structures 512a of FIG. 5B) extending along the first direction in the first connection region. Forming the first array semiconductor structure further includes forming first word line connection structures (e.g., the word line connection structures 514a of FIG. 5B) extending through the first stack along the first direction in the first connection region.

In some implementations, forming the second array semiconductor structure includes forming second word line contact structures (e.g., the word line contact structures 512b of FIG. 5B) extending along the first direction. The second word line contact structures are configured to be coupled to the first word line connection structures through the second interconnect layer.

In some implementations, for example, as shown in FIG. 7A (2), the first word line connection structures (e.g., the word line connection structures 714a-1 of FIGS. 7A (1)-7A (2)) and the first word line contact structures (e.g., the word line contact structures 712a of FIGS. 7A (1)-7A (2)) are arranged along a line extending in the second direction, the first word line connection structures are next to each other, and the first word line contact structures are next to each other.

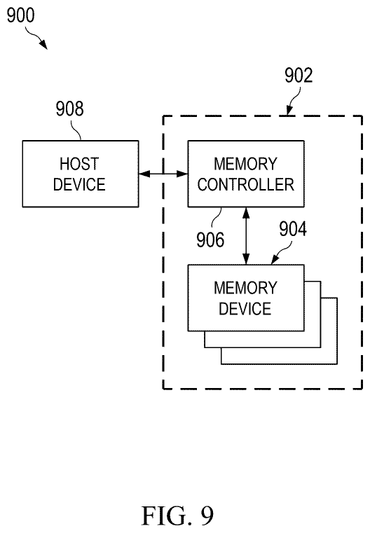

FIG. 9 illustrates a block diagram of an example system 900. The system 900 can have one or more semiconductor devices (e.g., memory devices), according to one or more implementations of the present disclosure. The system 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 9, the system 900 can include a host device 908 and a memory system 902 having one or more memory devices 904 and a memory controller 906. Host device 908 can include a processor of an electronic device, such as a central processing unit (CPU), or a system-on-chip (SoC), such as an application processor (AP). Host device 908 can be configured to send or receive data to or from the one or more memory devices 904.

A memory device 904 can be any memory device disclosed in the present disclosure, such as a memory device (e.g., a NAND Flash memory) as shown as the 3D memory device 100 of FIG. 1, the semiconductor device 500 of FIGS. 5A-5D, the semiconductor device 600 of FIGS. 6A-6D, or the semiconductor device 700 of FIGS. 7A (1)-7E (2). Memory controller 906 (a.k.a., a controller circuit) is coupled to memory device 904 and host device 908. Consistent with implementations of the present disclosure, memory device 904 can include a plurality of conductive interconnections through a cover layer that are in contact with conductive pads in a conductive pad layer, and memory controller 906 can be coupled to memory device 904 through at least one of the plurality of conductive interconnections. Memory controller 906 is configured to control memory device 904. For example, memory controller 906 may be configured to operate a plurality of channel structures via word lines. Memory controller 906 can manage data stored in memory device 904 and communicate with host device 908.

In some implementations, memory controller 906 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 906 can be configured to control operations of memory device 904, such as read, erase, and program (or write) operations. Memory controller 906 can also be configured to manage various functions with respect to the data stored or to be stored in memory device 904 including, but not limited to bad-block management, garbage collection, logical-to-physical address conversion, wear leveling, etc. In some implementations, memory controller 906 is further configured to process error correction codes (ECCs) with respect to the data read from or written to memory device 904. Any other suitable functions may be performed by memory controller 906 as well, for example, formatting memory device 904.

Memory controller 906 can communicate with an external device (e.g., host device 908) according to a particular communication protocol. For example, memory controller 906 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 9, memory controller 906 and a single memory device 904 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +−.10%, .+- .20%, or. +−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a control semiconductor structure; and
array semiconductor structures stacked along a first direction and coupled to the control semiconductor structure, wherein the array semiconductor structures comprise at least:
a first array semiconductor structure comprising:
a first array region and a first connection region adjacent to the first array region along a second direction perpendicular to the first direction;
a first stack of conductive layers and isolating layers alternating with each other along the first direction;
a first interconnect layer;
first bit lines in the first array region;
first bit line connection structures in the first array region, wherein the first bit line connection structures are coupled to the first bit lines and extend through the first stack along the first direction;
first word line contact structures extending along the first direction in the first connection region; and
first word line connection structures extending through the first stack along the first direction in the first connection region; and
a second array semiconductor structure comprising:
a second interconnect layer;
second bit lines coupled to the first bit line connection structures through the second interconnect layer; and
second word line contact structures extending along the first direction and being coupled to the first word line connection structures through the second interconnect layer.

2. The semiconductor device of claim 1, wherein:
one of the first bit line connection structures is coupled to a corresponding first bit line of the first bit lines and a corresponding second bit line of the second bit lines, and the corresponding first bit line of the first bit lines and the corresponding second bit line of the second bit lines are aligned along the first direction; and
one of the first word line connection structures is coupled to a corresponding second word line contact structure of the second word line contact structures.

3. The semiconductor device of claim 1, wherein the control semiconductor structure is bonded to the first array semiconductor structure through a first bonding structure, and the first array semiconductor structure is bonded to the second array semiconductor structure through a second bonding structure.

4. The semiconductor device of claim 1, wherein the first array semiconductor structure further comprises a first conductive structure outside the first array region and the first connection region, the first conductive structure is coupled to the control semiconductor structure through the first interconnect layer, the second array semiconductor structure further comprises a second conductive structure, the second conductive structure is coupled to the first conductive structure through the second interconnect layer, and the second conductive structure is aligned with the first conductive structure along the first direction.

5. The semiconductor device of claim 4, wherein the first array semiconductor structure further comprises a third interconnect layer, the first stack is between the first interconnect layer and the third interconnect layer along the first direction, and the first bit line connection structures, the first word line connection structures, and the first conductive structure are coupled between the first interconnect layer and the third interconnect layer.

6. The semiconductor device of claim 4, wherein:
the first array semiconductor structure comprises a first peripheral region adjacent to the first array region and the first connection region along a third direction perpendicular to the first direction and the second direction, wherein the first conductive structure is in the first peripheral region; and
the first array region comprises a center region and an edge region arranged along the third direction, wherein the edge region is in one side of the first array region along the third direction, the first bit line connection structures are in the edge region, and the center region is between the edge region and the first peripheral region along the third direction.

7. The semiconductor device of claim 4, wherein:
the first array semiconductor structure comprises a first peripheral region adjacent to the first array region and the first connection region along a third direction perpendicular to the first direction and the second direction, wherein the first conductive structure is in the first peripheral region; and
the first array region comprises a center region, a first edge region, and a second edge region arranged along the third direction, wherein the first edge region and the second edge region are in two opposite sides of the first array region along the third direction, a first set of the first bit line connection structures are in the first edge region, a second set of the first bit line connection structures are in the second edge region, the center region is between the first edge region and the second edge region along the third direction, and the second edge region is between the center region and the first peripheral region along the third direction.

8. The semiconductor device of claim 1, wherein the first word line connection structures and the first word line contact structures are arranged along a line extending in the second direction, the first word line connection structures are next to each other, and the first word line contact structures are next to each other.

9. The semiconductor device of claim 1, wherein the first word line connection structures and the first word line contact structures are arranged along a line extending in the second direction, and each of the first word line connection structures is next to a corresponding first word line contact structure of the first word line contact structures.

10. The semiconductor device of claim 1, wherein the first word line connection structures are arranged along a first line extending in the second direction, the first word line contact structures are arranged along a second line extending in the second direction, and the first word line connection structures are adjacent to the first word line contact structures along a third direction perpendicular to the first direction and the second direction.

11. The semiconductor device of claim 1, wherein the control semiconductor structure comprises:
page buffer circuits, wherein one of the page buffer circuits is coupled to a corresponding first bit line of the first bit lines and a corresponding second bit line of the second bit lines, the corresponding first bit line of the first bit lines is coupled to the corresponding second bit line of the second bit lines through a first bit line connection structure of the first bit line connection structures;
first string drivers coupled to the first word lines contact structures; and
second string drivers coupled to the second word lines contact structures through the first word line connection structures.

12. A semiconductor device, comprising:
a control semiconductor structure; and
array semiconductor structures stacked along a first direction and coupled to the control semiconductor structure, wherein the array semiconductor structures comprise at least a first array semiconductor structure, a second array semiconductor structure, and a third array semiconductor structure, and wherein:
the first array semiconductor structure comprises:
a first array region and a first connection region adjacent to the first array region along a second direction perpendicular to the first direction;
a first stack of conductive layers and isolating layers alternating with each other along the first direction;
a first interconnect layer;
first bit lines in the first array region;
first bit line connection structures in the first array region, wherein the first bit line connection structures are coupled to the first bit lines and extend through the first stack along the first direction;
first word line contact structures extending along the first direction in the first connection region; and
first word line connection structures extending through the first stack along the first direction in the first connection region;
the second array semiconductor structure comprises:
a second array region and a second connection region adjacent to the second array region along the second direction;
a second stack of conductive layers and isolating layers alternating with each other along the first direction;
a second interconnect layer;
second bit lines in the second array region, wherein the second bit lines are coupled to the first bit line connection structures;
second bit line connection structures in the second array region, wherein the second bit line connection structures are coupled to the second bit lines and extend through the second stack along the first direction;
second word line contact structures extending along the first direction in the second connection region and being coupled to a first set of the first word line connection structures through the second interconnect layer; and
second word line connection structures extending through the second stack along the first direction in the second connection region and being coupled to a second set of the first word line connection structures through the second interconnect layer;
the third array semiconductor structure comprises:
a third interconnect layer;
third bit lines coupled to the second bit line connection structures; and
third word line contact structures extending along the first direction and being coupled to the second word line connection structures through the third interconnect layer; and
a quantity of the first word line connection structure is equal to or greater than a sum of a quantity of the second word line contact structures and a quantity of the third word line contact structures.

13. The semiconductor device of claim 12, wherein the first array semiconductor structure further comprises a first conductive structure outside the first array region and the first connection region, the first conductive structure is coupled to the control semiconductor structure though the first interconnect layer, the second array semiconductor structure further comprises a second conductive structure outside the second array region and the second connection region, the second conductive structure is coupled to the first conductive structure through the second interconnect layer, the third array semiconductor structure further comprises a third conductive structure coupled to the second conductive structure through the third interconnect layer, and the first conductive structure, the second conductive structure, and the third conductive structure are aligned along the first direction.

14. The semiconductor device of claim 13, wherein:
the first array semiconductor structure comprises a first peripheral region adjacent to the first array region and the first connection region along a third direction perpendicular to the first direction and the second direction, and the first conductive structure is in the first peripheral region; and
the first array region comprises a center region and an edge region arranged along the third direction, the edge region is in one side of the first array region along the third direction, the first bit line connection structures are in the edge region, and the center region is between the edge region and the first peripheral region along the third direction.

15. The semiconductor device of claim 12, wherein the control semiconductor structure comprises:
page buffer circuits, wherein one of the page buffer circuits is coupled to a corresponding first bit line of the first bit lines, a corresponding second bit line of the second bit lines, and a corresponding third bit line of the third bit lines, wherein the corresponding first bit line of the first bit lines is coupled to the corresponding second bit line of the second bit lines through a first bit line connection structure of the first bit line connection structures, and the corresponding second bit line of the second bit lines is coupled to the corresponding third bit line of the third bit lines through a second bit line connection structure of the second bit line connection structures;
first string drivers coupled to the first word lines contact structures;
second string drivers coupled to the second word lines contact structures through the first set of the first word line connection structures; and
third string drivers coupled to the third word lines contact structures through the second set of the first word line connection structures and the second word line connection structures.

16. The semiconductor device of claim 12, wherein the first set of the first word line connection structures are arranged along a first line extending in the second direction, the second set of the first word line connection structures are arranged along a second line extending in the second direction, the first word line contact structures are arranged along a third line extending in the second direction, and the first word line contact structures are between the first set of the first word line connection structures and the second set of the first word line connection structures along a third direction perpendicular to the first direction and the second direction.

17. A method for forming a semiconductor device, comprising:
forming a first array semiconductor structure of the semiconductor device, wherein the first array semiconductor structure comprises:
a first array region and a first connection region adjacent to the first array region along a second direction perpendicular to a first direction;
a first stack of conductive layers and isolating layers alternating with each other along the first direction;
a first interconnect layer; and
first bit lines in the first array region;
forming a second array semiconductor structure of the semiconductor device, wherein the second array semiconductor structure comprises:
a second interconnect layer; and
second bit lines;
forming a control semiconductor structure of the semiconductor device, wherein the control semiconductor structure comprises peripheral circuits configured to control the first array semiconductor structure and the second array semiconductor structure; and
stacking the control semiconductor structure, the first array semiconductor structure, and the second array semiconductor structure along the first direction.

18. The method of claim 17, further comprising:
bonding the control semiconductor structure to the first array semiconductor structure using a first bonding structure; and
bonding the first array semiconductor structure to the second array semiconductor structure using a second bonding structure.

19. The method of claim 17, wherein forming the first array semiconductor structure comprises forming:
first bit line connection structures in the first array region, wherein the first bit line connection structures are coupled to the first bit lines and extend through the first stack along the first direction, and the first bit line connection structures are coupled to the second bit lines;
first word line contact structures extending along the first direction in the first connection region; and
first word line connection structures extending through the first stack along the first direction in the first connection region;
and wherein forming the second array semiconductor structure comprises forming second word line contact structures extending along the first direction, wherein the second word line contact structures are configured to be coupled to the first word line connection structures through the second interconnect layer.

20. The method of claim 19, wherein the first word line connection structures and the first word line contact structures are arranged along a line extending in the second direction, the first word line connection structures are next to each other, and the first word line contact structures are next to each other.
